(19) United States
(12) Patent Application Publication
(10) Pub. No.: US 2026/0211315 A1
(43) Pub. Date: Jul. 23, 2026

(54) METHOD AND DEVICE FOR MASK REPAIR

(71) Applicant: Carl Zeiss SMT GmbH, Oberkochen (DE)

(72) Inventors: Christian Felix Hermanns, Frankfurt (DE); Christian Rensing, Bensheim (DE); Thorsten Hofmann, Rodgau (DE); Gerson Mette, Hoesbach (DE)

(21) Appl. No.: 19/567,690

(22) Filed: Mar. 16, 2026

Related U.S. Application Data
(63) Continuation of application No. PCT/EP2024/076443, filed on Sep. 20, 2024.

(30) Foreign Application Priority Data
Sep. 21, 2023 (DE) 102023209230.1

(51) Int. Cl. G03F 1/74

(52) U.S. Cl. CPC G03F 1/74

(57) ABSTRACT

The present invention relates to a method for repairing a defect of a cap layer of a mask for lithography. The method comprises the step of depositing a deposition material on at least a portion of the cap layer and/or a multilayer of the mask, such that at least the defect of the cap layer is covered by the deposition material.

### CROSS-REFERENCE TO RELATED APPLICATIONS

This application is a continuation of and claims benefit under 35 U.S.C. § 120 from PCT application PCT/EP2024/076443, filed on Sep. 20, 2024, which claims priority from German patent application DE 10 2023 209 230.1, entitled “Verfahren und Vorrichtung zur Maskenreparatur” and filed on Sep. 21, 2023. The entire contents of each of these earlier applications are incorporated herein by reference.

### TECHNICAL FIELD

The present invention relates to a method, to a computer program, and to a device for processing of a mask for lithography.

### BACKGROUND

Increasingly smaller structures are being produced in the semiconductor industry in order to enable better semiconductor components and electronic circuits. Among the methods used for the production of structures are lithography methods which image these structures on a target plane, for example a wafer. The lithography methods may include, for example, photolithography, ultraviolet (UV) lithography, DUV lithography (i.e., lithography in the deep ultraviolet spectral region), EUV lithography (i.e., lithography in the extreme ultraviolet spectral region), x-ray lithography, nanoimprint lithography, etc. The lithography methods make use of masks (e.g., photomasks, exposure masks, reticles, stamps in the case of nanoimprint lithography, etc.), which comprise a pattern for imaging the desired structures onto the target plane.

A mask for lithography must satisfy numerous physical and chemical properties in order to assure the desired results in the lithography operation. However, the mask will not always be in an ideal state. For instance, faults or defects in the mask can lead to a deterioration in the lithographic image in the lithography operation and lead, for example, to defective structures in further processing. It is likewise possible for faults or defects in the mask to impair the stability of the mask and, for example, to minimize the lifetime thereof and hence increase the costs for the lithography operation. This is undesirable in a technical and industrial environment.

It is therefore the general aspect of the present invention to enable a solution for this situation.

### SUMMARY

This general aspect is at least partly achieved by the various aspects of the present invention.

A first aspect relates to a method of processing a mask for lithography, comprising: providing a gas and a particle beam on the mask in order to at least partly eliminate any chemical and/or geometric variance of a defect site in a layer sequence of the mask from a target property, wherein the layer sequence is adjoined by an imaging structure of the mask and the layer sequence comprises one or more layers.

The layer sequence may be regarded, for example, as a platform for the mask on which the imaging structures of the mask are mounted.

Existing approaches for correction of masks are based mainly on correcting any variance of the imaging structures of the mask. For instance, repairs of defective imaging structures by particle beam-induced processes are known. A defect in an imaging structure may be, for example, absent material that should actually be present according to the design of the imaging structure. Such defects are known as clear defects in lithography. A defect in an imaging structure may, for example, also be excess material that should actually not be present according to the design of the imaging structure. Such defects are known as opaque defects in lithography. By virtue of the repairing of such defective imaging structures of masks, it has long been possible to reliably assure the desired optical properties in lithography.

To date, therefore, the layer sequence on which the imaging structures of a mask have been mounted has barely been paid any attention with regard to a possible impairment or optimization in lithography.

For example, DE102017205629A1 relates to repairing of a defect in a photolithography mask for the extreme ultraviolet (EUV) wavelength range via a diffraction-based form of repair.

For instance, it is known to date to deposit a complex diffraction structure alongside the imaging structures of the mask. This may be configured as a Fresnel-type zone plate and may fulfil a complicated set of optical properties, such that the diffraction effect induced causes an optical correction in lithography. This approach can address optical faults in EUV masks that result from defects in the multilayer structure of an EUV mask, where the multilayer structure is not part of an imaging structure of the mask. It is thus exclusively the optical defect in an EUV mask that has been addressed to date, which is also corrected by an optical means (for example a diffraction grating). The actual defect in the layer sequence bearing the imaging structures of the mask will inevitably still exist in this existing approach. In this known approach, the mask is merely corrected by putting on a “pair of glasses”.

The disclosure described herein of the first aspect relates, by contrast, to a different concept. This is because a chemical and/or geometric correction of the actual defect in the layer sequence is being undertaken. For instance, the gas provided and the particle beam have the effect that the (chemical and/or geometric) variance in the defect site from its (chemical and/or geometric) target property is at least partly eliminated. The defect site is thus repaired via the gas and the particle beam and may thereafter also be referred to as a repaired site. The approach described herein addresses the actual physical fault in the layer sequence chemically and/or geometrically, which means that an optical correction of the mask is then enabled. It is thus not absolutely necessary to make use of an optical component as correction means.

The target property may comprise, for example, the corresponding property of the layer sequence at a non-defect site. For example, a definition may thus be made of what technical specifications the layer sequence has to fulfil as target property (i.e., at a non-defect site). The target property may thus be based on defined values. It is likewise possible to assume, for example, that a majority of the layer sequence satisfies the target property and that any variance therefrom is perceptible via noticeable characteristics. The target property in such a case may thus be based on a relative change in a property at a site compared to the majority of the layer sequence. This variance may be determined, for example, analytically via a measurement.

The gas and the particle beam can be provided so as to cause a particle beam-induced reaction of the layer sequence. This particle beam-induced reaction can be stopped in that the variance from the target property is at least partly eliminated.

Accordingly, by the providing of the gas and the particle beam, it is possible to implement a kind of closed-loop control circuit that reduces the chemical and/or geometric variance of a defect site in the layer sequence from a corresponding chemical and/or geometric target property. In one example, the chemical and/or geometric variance in the defect site from the target property can be essentially entirely eliminated. In one example, the chemical and/or geometric variance of the defect site from the target property may still exist after the method, but be less marked than before the performance of the method described herein.

The inventors have recognized that the approach of the disclosure described herein can serve for a more comprehensive set of defects in the layer sequence described. It is likewise not absolutely necessary to create a complex optical component, the properties of which first have to be calculated in a complex manner. By the approach described herein, by contrast, it is possible to remedy a multitude of defects in the layer sequence of the mask in a targeted manner since the actual physical defect in the layer sequence is corrected. It is thus possible, for example, to dispense with complicated optical calculations for defect correction in an industrial environment and to enable lower method complexity. By the approaches described herein, it is thus possible, for example, to enable a higher throughput in mask correction.

In one example, there may be a variance in a thickness of a material of the layer sequence at the defect site. For example, the thickness of a layer material of the layer sequence may thus be too high or too low. The variation in thickness may be regarded as a geometric variance and also be referred to as an unwanted geometric property. The variation in thickness may of course alternatively be associated with a chemical variance. For instance, the variation in thickness may arise from a chemical variance at the defect site, which results in a change in volume by comparison with non-defect sites.

In one example, a material in the layer sequence may be absent at the defect site. This can likewise be regarded as a variation in thickness. The target property here would be that specifically no material in the layer sequence should be absent. There is thus at least a geometric variance. For example, a material in the layer sequence may be at least partly absent. For instance, a layer material of a layer in the layer sequence may be at least partly absent, although layer material of this layer is still present at the defect site. In another example, a layer material of the layer sequence may also be completely absent at the defect site. This too can be regarded as a variation in thickness, although the thickness in this case would essentially tend to zero.

The absent material in the layer sequence may be recognizable, for example, via an edge or change in topology at a surface of the layer sequence.

By the particle beam-induced reaction (described herein) via the provision of the gas and the particle beam, it is possible to produce material such that the defect site is filled with material. It is thus possible to reduce the variance in this defect site (resulting from the absent material) from the desired target property. The target property may be defined here in that the defect site should actually have corresponding material. By this approach, it is possible to correct optical properties of the mask that arise from the absent material. For example, as a result of the absent material, an absorption, a phase shift, a reflectivity and/or a refractive index of the mask may thus be incorrect, which is at least partly corrected by the method.

The method may be effected, for example, in such a way that the relative variance in the reflectivity at the repaired site by comparison with the reflectivity at a non-defect site is, for example, 0% to 50%, preferably 0% to 30%, more preferably 0% to 10% and even more preferably 0%-5%. A higher variance in the reflectivity at a repaired site by comparison with a non-defect site is also possible, for example a variance greater than 50%, greater than 60% or greater than 70%. Such variances in the reflectivity may be chosen when this does not significantly alter the stability properties at the repaired site (for example, stability properties with regard to cleaning and exposure of the mask) by comparison with those at a non-defect site. As described herein, in one example, the layer sequence of the imaging structure may comprise an outer layer for protection of a reflective layer stack of the mask, where the outer layer comprises the defect site. It is possible, for example, for outer layer material to be absent. In this regard, it should already be mentioned at this juncture that, in the repair of absent material of an outer layer, the height of the material applied at the defect site can be chosen such that the height of the applied material does not have any significant variance from the height (or thickness) of the outer layer at a non-defect site. For example, the height of the material applied at the defect site may not be significantly higher or lower than the height (or thickness) of the outer layer at a non-defect site. For example, the thickness of a defect-free outer layer may be in a region of a few nanometers (for example, a defect-free outer layer may have a thickness of less than 10 nm). Because the thickness of the material at the repaired site does not significantly exceed the thickness of the outer layer at a non-defect site, it can be made possible for the properties with regard to reflectivity to be able to be achieved at the repaired site (and, for example, with assurance of the stability properties mentioned). In addition, the thickness of the repair material applied at the defect site may be less than the thickness of a defective outer layer if this does not significantly alter the stability properties (for example, with regard to cleaning and exposure) compared to those of the non-defect site.

For example, there may also be excess material at the defect site by comparison with the desired target property present, for example, at a non-defect site (for example, at a non-defect layer structure) of the mask. There may thus be too much material at the defect site compared to the amount desired (for example, from the mask design). For example, a layer material in the layer sequence at the defect site may have a higher thickness than at a non-defect site. It is likewise possible for there to be extraneous material (added on) at the defect site that should actually not be present there (and does not correspond, for example, to any layer material in the layer sequence).

The excess material at the defect site in the layer sequence may likewise be recognizable via an edge or change in topology at a surface of the layer sequence. There may be here an elevation at the defect site by comparison with surrounding non-defect sites.

By the particle beam-induced reaction (described herein) via the provision of the gas and the particle beam, it is possible to remove material such that the excess material at the defect site is at least partly removed. It is thus possible to reduce the variance in this defect site (resulting from the excess material) from the desired target property. The target property may be defined here in that the defect site should actually not have the excess material.

By the approach described herein, it is possible to reduce the amount of excess material at the defect site (since the excess material is at least partly removed), for example, in terms of area and/or height. It is thus possible to correct optical properties of the mask that arise from the excess material. For example, as a result of the excess material, an absorption, a phase shift and/or a refractive index of the mask may thus be incorrect, which is at least partly corrected by the method.

In one example, there may be a variance in the chemical composition at the defect site. This may also be referred to as an unwanted chemical composition. This variance in the chemical composition by comparison with a predetermined chemical target property (for example, a chemical target composition) may be at least partly reduced by the method described herein.

For example, by the particle beam-induced reaction (described herein) via the provision of the gas and the particle beam, it is possible to influence the chemical properties of the defect site of the layer sequence. For instance, it is conceivable that the particle beam-induced reaction penetrates material at the defect site and modifies the chemical composition thereof. It is thus possible, for example, to remove substances from the defect site in order to move closer to the chemical target composition (as described herein).

It is likewise possible that, by use of the particle beam-induced reaction, the material having the unwanted chemical composition is first (at least partly) removed at the defect site. The fault mentioned thus exists in that a material in the layer sequence is absent at the defect site.

Subsequently, this fault can be remedied as described by use of a particle beam-induced reaction in which production of material takes place, such that the defect site is filled with material.

It is thus possible to correct optical properties of the mask that arise from the unwanted chemical composition in the layer sequence. For example, as a result of the unwanted chemical composition, an absorption, a phase shift and/or a refractive index of the mask may thus be incorrect, which is at least partly corrected by the method described.

In one example, there may be a variance in the surface roughness at the defect site. For example, by the particle beam-induced reaction (described herein) via the provision of the gas and the particle beam, it is possible to influence the surface roughness of the defect site of the layer sequence. For instance, via the provision of the gas and the particle beam, material can be produced on the surface so as to alter the roughness thereof. It is likewise possible via the provision of the gas and the particle beam to remove material on the surface so as to alter the roughness thereof. It is thus possible to reduce the variance in this defect site (resulting from the unwanted surface roughness) from the desired target property.

It is thus possible to correct optical properties of the mask that arise from the unwanted surface roughness in the layer sequence. For example, as a result of the unwanted surface roughness, an absorption, a phase shift and/or a refractive index of the mask may thus be incorrect, which is at least partly corrected by the change in the surface roughness described.

Details of the methods described herein are elucidated in detail and set out hereinafter. In particular, specific process gases, process gas mixtures and process steps are disclosed in order to illustrate the implementation of the methods. For instance, details relating to the particle beam-induced reactions indicated are elucidated, where removal or production of material takes place. In one example, the providing of the gas may comprise providing a deposition gas for deposition of deposition material at the defect site. For instance, in the course of the method, via the provision of the particle beam (for example, an electron beam) with the deposition gas, it is possible to implement a particle beam-induced deposition reaction in a targeted manner. The deposition gas may be provided, for example, locally on the mask (for example, via a nozzle).

In one example, the deposition gas may include any metal complex. For example, the deposition gas may comprise any metal carbonyl. In one example, the deposition gas may comprise any metal halide.

In one example, the deposition gas may comprise at least one of the following: a metal phosphine, a metal carboxylate, a metal hydride, a metal alkyl, a metal betadiketonate. The deposition gas may also comprise a metal complex having polyhaptic ligands, for example, aromatic ligands.

In one example, the deposition gas may comprise ruthenium. In such a case, the corresponding deposition material may likewise include ruthenium. A deposition gas comprising ruthenium may be used, for example, when the layer sequence mentioned comprises ruthenium. For example, this may be advantageous when there is a lack of material at the defect site that should include ruthenium. The filling of this defect site with ruthenium-containing deposition material can ensure that the optical properties of this filler material correspond essentially to the absent material. This is because the absent material would likewise include ruthenium, and so at least a similar refractive index of the two materials can be assumed.

In one example, the deposition gas may comprise at least one of the following: allylruthenium(II) tricarbonyl bromide, allylruthenium(II) tricarbonyl chloride, benzeneruthenium(II) chloride dimer, bis(2,4-dimethylpentadienyl)ruthenium, bis(cyclopentadienyl)ruthenium(II), bis(ethylcyclopentadienyl)ruthenium(II), carbonylchlorohydridotris(triphenylphosphine)ruthenium(II), chloro(4,4′-dicarboxy-2,2′-bipyridine)(p-cymene)ruthenium(II) chloride, chloro(cyclopentadienyl)bis(triphenylphosphine)ruthenium(II), chloropentaammineruthenium(III) chloride, dicarbonylcyclopentadienylruthenium dimer, dichloro(p-cymene)ruthenium(II) dimer, dichlorotricarbonylruthenium(II) dimer, dichlorotris(triphenylphosphine)ruthenium(II), dihydrotetrakis(triphenylphosphine)ruthenium(II), hexaammineruthenium(III) chloride, (hexamethylbenzene)ruthenium(II) dichloride dimer, (p-cymene)(N,N′-diisopropyl-1,2-ethanediimine)ruthenium, ruthenium pentacarbonyl, ruthenium tetracarbonyl iodide, ruthenium(III) acetylacetonate, ruthenium(III) bromide, ruthenium(III) chloride, ruthenium(III) nitrosylacetate, ruthenium(III) nitrosylchloride monohydrate, ruthenium(III) nitrosylnitrate, ruthenium(III) nitrosylsulfate, ruthenium(IV) sulfide, ruthenium(VIII) oxide, tetraamminechlorohydroxyruthenium(III) chloride, tetrakis(dimethyl sulfoxide)dichlororuthenium(II), (toluene)(1,5-cyclooctadiene)ruthenium, triruthenium dodecacarbonyl, tris(2,2′-bipyridyl)ruthenium(II) chloride.

These are deposition gases including ruthenium. By use of these deposition gases, it is thus possible to produce a deposition material comprising ruthenium at the defect site of the layer sequence.

In one example, the deposition gas may comprise rhodium. In such a case, the corresponding deposition material may likewise include rhodium. A deposition gas comprising rhodium may be used, for example, when the layer sequence mentioned comprises rhodium. For example, this may be advantageous when there is a lack of material at the defect site that should include rhodium. The filling of this defect site with rhodium-containing deposition material can ensure that the optical properties of this filler material correspond essentially to the absent material. This is because the absent material would likewise include rhodium, and so at least a similar refractive index of the two materials can be assumed.

In one example, a deposition gas comprising rhodium may be used when the layer sequence mentioned comprises ruthenium. For example, this may be advantageous when there is a lack of material at the defect site that should include ruthenium. The filling of this defect site with rhodium-containing deposition material can ensure that the optical properties of this filler material enable an optical correction of the mask.

In one example, a deposition gas comprising ruthenium may be used when the layer sequence mentioned comprises rhodium. For example, this may be advantageous when there is a lack of material at the defect site that should include rhodium. The filling of this defect site with ruthenium-containing deposition material can ensure that the optical properties of this filler material enable an optical correction of the mask.

In one example, the deposition gas may comprise at least one of the following: acetylacetonatobis(ethylene)rhodium(I), chlorobis(ethylene)rhodium(I) dimer, dicarbonyl(2,4-pentanedionato)rhodium(I), di-eta-chloro-tetrakis(phosphorus trifluoride)dirhodium, dirhodium(II) tetrakis(caprolactam), di-μ-chloro-tetracarbonyldirhodium(I), hexarhodium hexadecacarbonyl, hydridotetrakis(triphenylphosphine)rhodium(I), pentaamminechlororhodium(III) dichloride, rhodium octanoate dimer, rhodium(II) acetate dimer, rhodium(II) trifluoroacetate dimer, rhodium(III) acetate, rhodium(III) chloride trihydrate, rhodium(III) chloride, rhodium(III) nitrate (anhydrous), rhodium(III) oxide (anhydrous), rhodium(III) trifluoroacetylacetonate, tetrakis(1,5-cyclooctadiene)tetra-μ-hydridotetrarhodium, tetrarhodium dodecacarbonyl.

These are deposition gases including rhodium. By use of these deposition gases, it is thus possible to produce a deposition material comprising rhodium at the defect site of the layer sequence.

In one example, the deposition gas may comprise boron. In such a case, the corresponding deposition material may likewise include boron. A deposition gas comprising boron may be used, for example, when the layer sequence mentioned comprises boron. For example, this may be advantageous when there is a lack of material at the defect site that should include boron. The filling of this defect site with boron-containing deposition material can ensure that the optical properties of this filler material correspond essentially to the absent material. This is because the absent material would likewise include boron, and so at least a similar refractive index of the two materials can be assumed.

The processes in which deposition gases comprise boron may be used, for example, when the layer sequence comprises boron, boron nitride (BN) and/or boron carbide (B₄C). In particular, it is possible to use processes with deposition gases comprising boron when there is a lack of material at the defect site that comprises boron, boron nitride (BN) and/or boron carbide (B₄C). For example, the deposition gas comprising boron may comprise a boron halide. In another example, the deposition gas comprising boron may comprise boron trichloride (BCl₃).

In one example, the deposition gas comprising a boron halide may be combined with an additive gas for deposition of the deposition material. As described herein, the provision of the gas may also comprise providing of an additive gas; some illustrative combinations of deposition gases with additive gases have already been described here. For example, the deposition gas may comprise a boron halide, where the additive gas may comprise ammonia (NH₃) and/or nitrogen (N₂). It is likewise possible in one example for the deposition gas to comprise boron trichloride (BCl₃), where the additive gas may comprise H₂-CH₄.

In one example, the deposition gas may comprise silicon. A deposition gas comprising silicon may be used, for example, when the layer sequence mentioned comprises silicon. For example, this may be advantageous when there is a lack of material at the defect site that should include silicon. The filling of this defect site with silicon-containing deposition material can ensure that the optical properties of this filler material correspond essentially to the absent material. This is because the absent material would likewise include silicon, and so at least a similar refractive index of the two materials can be assumed.

The processes in which deposition gases comprise silicon may be used, for example, when the layer sequence comprises silicon, silicon dioxide (SiO₂), silicon carbide (SiC) and/or silicon nitride (Si₃N₄). In particular, it is possible to use processes with deposition gases comprising silicon when there is a lack of material at the defect site that comprises silicon, silicon dioxide (SiO₂), silicon carbide (SIC) and/or silicon nitride (Si₃N₄).

For example, the deposition gas comprising silicon may comprise tetraisocyanatosilane. In another example, the deposition gas comprising silicon may comprise tetraethyl orthosilicate (TEOS).

For example, when the layer sequence comprises silicon dioxide, the deposition gas comprising silicon may comprise tetraisocyanatosilane. In another example, when the layer sequence comprises silicon dioxide, the deposition gas comprising silicon may comprise tetraethyl orthosilicate (TEOS).

In one example, the deposition gas comprising tetraisocyanatosilane may be combined with an additive gas for deposition of the deposition material. In one example, the deposition gas may comprise tetraisocyanatosilane, where the additive gas may comprise oxygen.

For example, the deposition gas comprising silicon may comprise silicon oxynitride (SiOₓN_{y}). Such a deposition gas may be produced using tetrakis(dimethylamino)silane (TKDMAS) or TEOS (see “Dissociative ionization and electron beam induced deposition of tetrakis(dimethylamino)silane, a precursor for silicon nitride deposition”; Po Yuan S. et al.; Phys. Chem. Chem. Phys.; Issue 16(2022 )).

For example, when the layer sequence comprises silicon carbide and/or silicon nitride, the deposition gas comprising silicon may comprise TKDMAS or TEOS.

In one example, the deposition gas may comprise titanium. A deposition gas comprising titanium may be used, for example, when the layer sequence mentioned comprises titanium. For example, this may be advantageous when there is a lack of material at the defect site that should include titanium. The filling of this defect site with titanium-containing deposition material can ensure that the optical properties of this filler material correspond essentially to the absent material. This is because the absent material would likewise include titanium, and so at least a similar refractive index of the two materials can be assumed.

The processes in which deposition gases comprise titanium may be used, for example, when the layer sequence comprises titanium dioxide (TiO₂) and/or titanium nitride (TiN). In particular, it is possible to use processes with deposition gases comprising titanium when there is a lack of material at the defect site that comprises titanium dioxide (TiO₂) and/or titanium nitride (TiN).

For example, the deposition gas comprising titanium may comprise titanium(IV) isopropoxide (Ti[OCH(CH₃)₂]₄).

In one example, the deposition gas may comprise zirconium. A deposition gas comprising zirconium may be used, for example, when the layer sequence mentioned comprises zirconium. For example, this may be advantageous when there is a lack of material at the defect site that should include zirconium. The filling of this defect site with zirconium-containing deposition material can ensure that the optical properties of this filler material correspond essentially to the absent material. This is because the absent material would likewise include zirconium, and so at least a similar refractive index of the two materials can be assumed.

The processes in which deposition gases comprise zirconium may be used, for example, when the layer sequence comprises zirconium dioxide (ZrO₂). In particular, it is possible to use processes with deposition gases comprising zirconium when there is a lack of material at the defect site that comprises zirconium dioxide (ZrO₂).

For example, the deposition gas comprising zirconium may comprise nitronium pentanitratozirconate (e.g., represented as ZN, [NO₂][Zr(NO₃)₅]).

In one example, the deposition gas may comprise palladium. A deposition gas comprising palladium may be used, for example, when the layer sequence mentioned comprises palladium. For example, this may be advantageous when there is a lack of material at the defect site that should include palladium. The filling of this defect site with palladium-containing deposition material can ensure that the optical properties of this filler material correspond essentially to the absent material. This is because the absent material would likewise include palladium, and so at least a similar refractive index of the two materials can be assumed.

For example, the deposition gas comprising palladium may comprise Pd(η³-allyl)(η⁵-cp).

In one example, the deposition gas may comprise niobium. A deposition gas comprising niobium may be used, for example, when the layer sequence mentioned comprises niobium. For example, this may be advantageous when there is a lack of material at the defect site that should include niobium. The filling of this defect site with niobium-containing deposition material can ensure that the optical properties of this filler material correspond essentially to the absent material. This is because the absent material would likewise include niobium, and so at least a similar refractive index of the two materials can be assumed.

For example, the deposition gas comprising niobium may include niobium(V) chloride (NbCl₅) and/or niobium(IV) fluoride (NbF₄).

In one example, the deposition gas may comprise chromium. For example, the deposition gas comprising chromium may comprise chromium hexacarbonyl (Cr(CO)₆).

In one example, the deposition gas may comprise tungsten. For example, the deposition gas comprising tungsten may comprise tungsten hexacarbonyl (W(CO)₆). In a further example, the deposition gas comprising tungsten may comprise tungsten hexachloride (WCl₆).

In one example, the providing of the gas may comprise providing an etch gas for removal of material at the defect site. For instance, in the course of the method, via the provision of the particle beam (for example, an electron beam) with the etch gas, it is possible to implement a particle beam-induced etch reaction in a targeted manner. The etch gas may be provided, for example, locally on the mask (for example, via a nozzle).

In one example, the providing of the etch gas may cause etching of material in the layer sequence. In this way, material may be removed at the defect site in the layer sequence. For example, the providing of the etch gas can enable etching of unwanted material at the defect site. The unwanted material may, for example, have a geometrically and/or chemically unwanted property (as described herein).

For example, excess material may thus result from a variation in thickness, where the material at the defect site is thicker than at a non-defect site. By use of the etching with the etch gas, the excess material can be etched in order to at least partly eliminate the variance in the thickness variation. For example, an unwanted elevation at the defect site resulting from a higher thickness can thus be levelled out or at least reduced via the etching.

In one example, the providing of the etch gas may cause etching of extraneous material at the defect site which is essentially absent at a non-defect site of the layer sequence. The extraneous material may, for example, also be regarded as excess material which is unwanted at the defect site (as described herein). The extraneous material may, for example, constitute an elevation by comparison with a non-defect site. By the method described herein, it is possible to etch an extraneous material added onto the layer sequence. The etching of the extraneous material is accompanied by a reduction in the volume thereof, which may lead to a correction of the defect site and the mask (as described herein).

The extraneous material may, for example, include oxygen and/or carbon. The extraneous material may, for example, include an oxide layer that has formed on the surface of the layer sequence.

In one example, the etch gas may comprise a halogen.

In one example, the halogen may comprise fluorine.

In one example, the etch gas may comprise xenon difluoride.

In one example, the provision of the etch gas for removal of material at the defect site may be followed by deposition of deposition material at the defect site. This two-stage procedure can be employed for several cases.

For example, a defect site having unwanted chemical and/or geometric properties may first be completely removed. Subsequently, however, the defect exists that material is absent at the defect site. To some degree, there is thus a transformation of the defect to the defined state that material is absent at the defect site. This can then be corrected again via the deposition of deposition material at the defect site, such that the optical properties of the mask are in spec, e.g., the deposition of deposition material at the defect site may be such as to reconstruct the optical properties of the mask sufficiently well. Reconstructing the optical properties of the mask sufficiently well may comprise that the optical properties of the (reconstructed) mask are such that the (reconstructed) mask can be used within a lithographic production workflow. It is possible here to take account of the disclosure described herein with regard to the deposition gases in terms of the materials of the layer sequence. It is likewise possible for this step with the deposition gas to use the additive gases described herein.

For example, the two-stage method may be employed for a defect site with material having an unwanted chemical composition. For example, the material having the unwanted chemical property may be present in a first material layer of the layer sequence.

In a first example, the unwanted material may extend essentially across the entire height of this first material layer. This first material layer may be adjoined by a second material layer, but one that is not defective and has desired chemical properties. In the first step, at the defect site, the unwanted material of the first material layer may be completely removed until the second adjoining material layer is at least locally exposed. The etching of the unwanted material may in this case be configured selectively with respect to the adjoining second material layer in order that it is not significantly attacked by the process. For example, this can be effected by use of the etch gases (and additive gases) described herein. After the first step, the unwanted material has been removed, but the defined defect then exists that material is absent at the defect site. This can then be corrected again by the second step via the deposition of deposition material.

In a further example, the material having the unwanted chemical property at the defect site may extend only partly across the first material layer. For example, the first material layer may have been only partly chemically modified (for example, as far as a particular height). In this example too, the first material layer may be adjoined by a second material layer. In the first step of the two-stage method, it is possible here to etch the unwanted material of the first material layer, although the adjoining second material layer is not exposed. The etching may thus at least remove the unwanted material of the first material layer, leaving desired material of the first material layer. After the first step, in this example too, the unwanted material has been removed, but the defined defect then exists that material is absent at the defect site. This can then be corrected by the second step via the deposition of deposition material.

The two-stage method can also be employed as a correction mechanism if there has been etching of wanted (non-defective) material in a method described herein comprising etching of unwanted material at the defect site. It is possible, for example, for unwanted overetching to have taken place, even though this was not intended. Therefore, the defect that material is absent at the defect site was thus introduced parasitically via the particle beam-induced method. This defect can then be corrected again via the deposition with the deposition gas.

For example, the two-stage method may also be employed for a defect site where material is partly absent. For example, material of a first material layer in the layer sequence may be partly absent, where the first material layer is adjoined by a second material layer. Firstly, it would be possible to make up the absent material in the first material layer by use of a deposition.

However, it is also conceivable that the two-stage method is employed. In the first step, at the defect site, the remaining material of the first material layer may be completely removed until the second adjoining material layer is at least locally exposed. The etching of the unwanted material may in this case be configured selectively with respect to the adjoining second material layer in order that it is not significantly attacked by the process. The defect site is thus in a defined state. To wit, material of the first material layer is absent up to the second material layer. Thus, the height of the absent material can be assumed to be the height of the first material layer. This defined, but incorrect, state can then be corrected by the second step via the deposition of deposition material.

In one example, the providing of the etch gas may cause removal of at least one substance intercalated in the layer sequence. For example, the particle beam-induced reaction with the etch gas may cause removal of intercalated oxygen. For example, via the particle beam-induced reaction, an intercalated substance may thus be reduced as the reaction product, such that it can exit from the defect site after transformation. For example, it is possible for this purpose to use a reducing agent as additive gas (as described herein).

In one example, after the deposition of deposition material at the defect site, it is possible to provide the etch gas for removal of material at the defect site. This may be used, for example, as a correction mechanism if too much material has been deposited in one of the methods described herein.

In one example, the layer sequence may comprise one or more outer layers for protection of a reflective layer stack of the mask, where the one or more outer layers comprise the defect site. The reflective layer stack may be designed, for example, to reflect a wavelength which is used for a lithography method on the mask. For example, the reflective layer stack may be a Bragg mirror. The reflective layer stack may be protected by use of the outer layers in order that the optical properties of the reflective layer stack cannot be easily impaired by outside influences.

The one or more outer layers may also fulfil optical properties, for example, in order not to adversely affect the optical properties of the reflective layer stack. However, the main function of the one or more outer layers is the protective function for the reflective layer stack (for example, mechanical and/or chemical protection). A surface of the one or more outer layers may be adjoined by the imaging structures of the mask. The one or more outer layers may thus be disposed between the layers of the imaging structures and the layers of the reflective layer stack. In the field of lithography masks, the outer layers mentioned are often referred to as “cap layer” or “capping layer”.

As mentioned, the defect site may be present in at least one outer layer. Thus, material of at least one outer layer may have a geometric and/or chemical variance. For example, material of at least one outer layer may be absent. For example, material of an outer layer may have an unwanted chemical composition. For example, a layer material of the outer layer may be locally thicker than at a non-defect site. It is likewise possible for extraneous material to be added onto at least one outer layer. As described, by the methods described herein, it is possible to at least partly eliminate any chemical and/or geometric variance of a defect site at least in an outer layer of the mask from a target property.

The height of an outer layer may, for example, be between 0.5 nm and 10 nm. For example, heights of an outer layer of the mask between 0.5 nm and 4 nm are also conceivable. In one example, the height of an outer layer may be between 2 nm and 3.5 nm.

If a defect site of the outer layer is corrected by use of particle beam-induced deposition, the height of the deposition material may be chosen, for example, such that the height of the deposition material is between 0.5 nm and 10 nm, preferably between 0.5 nm and 7 nm, more preferably between 0.5 nm and 4 nm. The height may be defined, for example, along a normal vector of a substrate plane of the mask.

In the case of absent material in the one or more outer layers, the height of the deposition material at the defect site may be chosen such that the height of the deposition material does not differ significantly from the height of the one or more outer layers at a non-defect site.

For example, the height of the deposition material at the repaired site may not be significantly higher or lower than the height of the one or more outer layers at a non-defect site.

For example, the method may be effected in such a way that the relative variance in the height of the deposition material at the repaired site by comparison with the height of the outer layer at a non-defect site is, for example, 0% to 30%, preferably 0% to 20%, more preferably 0% to 10% and even more preferably 0% to 5%.

In one example, in the case of absent material in the one or more outer layers, the height of the deposition material may be chosen such that the deposition material at the repaired site forms an excess height, where the plateau of the deposition material is higher than the plane formed by the one or more surrounding defect-free outer layers. This excess height compared to the plane may, for example, be less than 10 nm (for example, there may be a distance of less than 10 nm between the plateau of the deposition material and the plane). For example, the excess height compared to the plane may also be less than 8 nm, preferably less than 5 nm, more preferably less than 3 nm, even more preferably less than 2 nm, most preferably less than 1 nm.

In addition, or alternatively, the excess height compared to the plane may be less than the height of the outer layer, preferably less than 50% of the height of the outer layer, more preferably less than 30% of the height of the outer layer, even more preferably less than 10% of the height of the outer layer, most preferably less than 5% of the height of the outer layer.

In one example, in the case of absent material in the one or more outer layers, the height of the deposition material may be chosen such that a sink is formed at the repaired site, where the plateau of the deposition material is lower than the plane formed by the one or more surrounding defect-free outer layers. This lowering compared to the plane may, for example, be less than 50% of the total height of the one or more outer layers (for example, there may be a distance of less than 5 nm between the plateau of the deposition material and the plane).

Specifically, the lowering compared to the plane may be less than the total height of the one or more outer layers, than 50% of the total height of the one or more outer layers, than 30% of the total height of the one or more outer layers, than 10% of the total height of the one or more outer layers or than 5% of the total height of the one or more outer layers.

In addition, or alternatively, the lowering compared to the plane may, for example, be less than 10 nm (for example, there may be a distance of less than 10 nm between the plateau of the deposition material and the plane). For example, the lowering compared to the plane may be less than 5 nm, preferably less than 3 nm, more preferably less than 2 nm, even more preferably less than 1 nm, most preferably less than 0.5 nm.

As described, in the case of absent material of the outer layer, a correction can be effected by use of particle beam-induced deposition, with deposition of the deposition material at the defect site where material is absent. In such a case, the height of the deposition material may also be chosen such that there is no significant excess height of the deposition material based on the surface of the non-defective outer layer. A surface plateau of the deposition material may thus be essentially planar with the surface plateau of the surrounding non-defective outer layer.

Generally, the repair process may be adapted such as to ensure that too much deposited deposition material, e.g., excess material, can be removed again, e.g., after the deposition of the deposition material. For example, removing the too much deposited deposition material, e.g., the excess material, may comprise an adapted etching process, e.g., by a selective etching process. Specifically, the adapted etching process, e.g., the selective etching process, may be at least partially selective for the deposited deposition material compared to the material of an outer layer, e.g., compared to a material associated with a defect-free portion of the mask. In other words, the etching process may be adapted such as to not attack the material of an outer layer, or at least significantly less than the excess material.

Specifically, the outer layer may comprise at least a portion of a cap layer of the mask. In particular, the material of the outer layer may comprise material associated with the cap layer, e.g., a cap layer material. For example, when the repair process comprises a repair of a cap layer defect, the repair process may be adapted such that too much deposited deposition material can be removed, e.g., removed with respect to the cap layer. Particularly, the etching process may be at least partially selective for the deposition material compared to the cap layer material. In other words, the etching process may allow for at least partially etching the deposition material while at least partially maintaining the integrity of the cap layer, particularly maintaining the protective function of the cap layer, e.g., leaving the cap layer and/or the cap layer material essentially unchanged. In some embodiments, the repair process may comprise a selective etching process, e.g., selective for the deposition material compared to the cap layer material, when a repair of the respective layer, e.g., the cap layer, is performed locally, e.g., without removing at least a portion of the imaging structure of the mask.

In addition, or alternatively, the deposition material may be configured with a defined excess height, e.g., the defined excess height may be based on the surface of the non-defective outer layer (in order, for example, to assure the protective function and the optical correction of the mask). A surface plateau of the deposition material may thus be higher than a surface plateau of the surrounding non-defective outer layer. In a further example, it is also conceivable that a surface plateau of the deposition material is lower than the surface of the non-defective outer layer (in order, for example, to assure the protective function and the optical correction of the mask).

In one example, the material of the outer layer may have an amorphous structure. The material of the outer layer thus need not necessarily be polycrystalline.

In one example, at least one of the one or more outer layers may comprise ruthenium. In one example, the at least one outer layer may be formed predominantly from ruthenium. For example, the ruthenium content of the at least one outer layer may comprise at least 50 atom per cent (at %), at least 70 atom per cent, at least 80 atom per cent, or at least 90 atom per cent. In one example, the ruthenium content of the outer layer may essentially also comprise 100 atom per cent. But the method described herein of the first aspect is fundamentally also conceivable with a different ruthenium content of the at least one outer layer. For example, the ruthenium content of the at least one outer layer may be less than 50 atom per cent or less than 10 atom per cent, or less than 1 atom per cent. It is likewise conceivable that the ruthenium content of the at least one outer layer comprises at least 10 atom per cent or at least 25 atom per cent.

In one example, in the method of the first aspect, the outer layer comprising ruthenium comprises at least one further element. The further element may be regarded as part of any substance included in the ruthenium-containing outer layer (meaning that the further element may, for example, comprise part of a composite of matter, a chemical element, etc.). The material of the ruthenium-containing outer layer may therefore also be described (stoichiometrically) in the form of RuₐZ_{b} with a >0, b 24 0, where Z represents the further element (or one or more further chemical elements).

For example, the ruthenium-containing outer layer may further comprise oxygen. Oxygen may be regarded here as the second element described. For example, the at least one outer layer comprising ruthenium may include a ruthenium oxide (e.g. RuO₂).

In one example, the material of the ruthenium-containing outer layer may have an amorphous structure. The material of the ruthenium-containing outer layer thus need not necessarily be polycrystalline.

In one example, at least one of the one or more outer layers may comprise rhodium. In one example, the at least one outer layer may be formed predominantly from rhodium. For example, the rhodium content of the at least one outer layer may comprise at least 50 atom per cent (at %), at least 70 atom per cent, at least 80 atom per cent, or at least 90 atom per cent. In one example, the rhodium content of the outer layer may essentially also comprise 100 atom per cent. But the method described herein of the first aspect is fundamentally also conceivable with a different rhodium content of the at least one outer layer. For example, the rhodium content of the at least one outer layer may be less than 50 atom per cent or less than 10 atom per cent, or less than 1 atom per cent. It is likewise conceivable that the rhodium content of the at least one outer layer comprises at least 10 atom per cent or at least 25 atom per cent.

In one example, in the method of the first aspect, the outer layer comprising rhodium comprises at least one further element. The further element may be regarded as part of any substance included in the rhodium-containing outer layer (meaning that the further element may, for example, comprise part of a composite of matter, a chemical element, etc.). The material of the rhodium-containing outer layer may therefore also be described (stoichiometrically) in the form of RhₐZ_{b} with a >0, b≥0, where Z represents the further element (or one or more further chemical elements).

In one example, the material of the rhodium-containing outer layer may have an amorphous structure. The material of the rhodium-containing outer layer thus need not necessarily be polycrystalline.

Further possible materials of outer layers of a mask are disclosed in U.S. Pat. No. 6,724,462B1 (under the technical term: “capping layer”).

Further possible materials of outer layers of a mask are disclosed in U.S. Pat. No. 6,449,086B1 (under the technical term: “capping layer”).

Further possible materials of outer layers of a mask are disclosed in US2021/0349386 A1 (under the technical term: “capping layer”).

In one example, the layer sequence may comprise one or more layers of a reflective layer stack of the mask, where the one or more layers of the reflective layer stack comprise the defect site. Thus, material of at least one layer of the reflective layer stack may therefore have a geometric and/or chemical variance. For example, material of at least one layer of the reflective layer stack may be absent. For example, material of at least one layer of the reflective layer stack may have an unwanted chemical composition. For example, a layer material of at least one layer of the reflective layer stack may be locally thicker than at a non-defect site. It is likewise possible for extraneous material to be added onto at least one layer of the reflective layer stack. As described, by the methods described herein, it is possible to at least partly eliminate any chemical and/or geometric variance of a defect site in at least one layer of the reflective layer stack of the mask from a target property.

In one example, the method of the first aspect may further comprise: providing an etch gas and a particle beam for removal of material in order to expose part of the reflective layer stack, such that the chemical and/or geometric variance of the defect site from the target property can be at least partly eliminated. As mentioned, the one or more layers in the reflective layer stack may comprise the defect site. In order to arrive at this defect site, however, it may be necessary to first remove material. For example, the material to be removed may comprise layer material of the one or more outer layers of the mask that have been mentioned. It is likewise possible for the material to be removed to comprise layer material of the one or more layers of the reflective layer stack.

The defect site of the one or more layers of the reflective layer stack may be processed by the methods described herein. For example, it is thus possible to etch, in a particle beam-induced manner, material in the reflective layer stack that has a geometric and/or chemical variance. It is likewise possible via a particle beam-induced method to deposit material which then functions as corrective layer material in the reflective layer stack. For example, it is thus possible to etch a trench into the reflective layer stack. Subsequently, this trench may be filled again with deposition material. The deposition material may be chosen such that it conforms essentially to the optical properties of a non-defective material of the reflective layer stack.

In one example, the providing of the gas may further comprise providing of an additive gas. This may be added to the deposition gas or etch gas provided in order to configure the particle beam-induced reaction in a targeted manner (for example, with regard to selectivity, etch rate, passivation, etc.). An additive gas can also be used, for example, to achieve an elevated metal content in the deposition material, and it is also possible to enable fewer impurities, for example carbon. In some cases, the additive gas may, for example, also enable a higher deposition rate.

In one example, the additive gas may comprise oxygen. Such an additive gas may act, for example, as an oxidizing agent.

In one example, the additive gas may comprise hydrogen. Such an additive gas may act, for example, as a reducing agent.

In one example, the additive gas may comprise nitrogen.

In one example, the additive gas may comprise oxygen and hydrogen. In a further example, the additive gas may comprise oxygen and nitrogen. It is likewise possible that the additive gas comprises nitrogen and hydrogen. In another example, the additive gas may comprise oxygen, hydrogen and nitrogen.

In one example, the additive gas may comprise at least one of the following: NH₃, NO₂, H₂O, O₂. In one example, the additive gas may also comprise at least one of the following: NO, HNO₃, O₃, H₂O₂, N₂O.

In one example, the additive gas may be composed of two or more additive gases (with the properties of additive gases that are described herein). The additive gas may thus be a gas mixture of two or more (additive) gases. For example, the additive gas may comprise a gas mixture with a first additive gas comprising NO₂ and a second additive gas comprising H₂O.

In one example, the deposition gases mentioned may be combined with at least one of the additive gases mentioned for the particle beam-induced reaction.

In one example, the additive gas may comprise oxygen, where the deposition gas comprises at least one of the following ruthenium-containing deposition gases:
allylruthenium(II) tricarbonyl bromide, allylruthenium(II) tricarbonyl chloride, benzeneruthenium(II) chloride dimer, bis(2,4-dimethylpentadienyl)ruthenium, bis(cyclopentadienyl)ruthenium(II), bis(ethylcyclopentadienyl)ruthenium(II), carbonylchlorohydridotris(triphenylphosphine)ruthenium(II), chloro(4,4′-dicarboxy-2,2′-bipyridine)(p-cymene)ruthenium(II) chloride, chloro(cyclopentadienyl)bis(triphenylphosphine)ruthenium(II), chloropentaammineruthenium(III) chloride, dicarbonylcyclopentadienylruthenium dimer, dichloro(p-cymene)ruthenium(II) dimer, dichlorotricarbonylruthenium(II) dimer, dichlorotris(triphenylphosphine)ruthenium(II), dihydrotetrakis(triphenylphosphine)ruthenium(II), hexaammineruthenium(III) chloride, (hexamethylbenzene)ruthenium(II) dichloride dimer, (p-cymene)(N,N′-diisopropyl-1,2-ethanediimine)ruthenium, ruthenium pentacarbonyl, ruthenium tetracarbonyl iodide, ruthenium(III) acetylacetonate, ruthenium(III) bromide, ruthenium(III) chloride, ruthenium(III) nitrosylacetate, ruthenium(III) nitrosylchloride monohydrate, ruthenium(III) nitrosylnitrate, ruthenium(III) nitrosylsulfate, ruthenium(IV) sulfide, ruthenium(VIII) oxide, tetraamminechlorohydroxyruthenium(III) chloride, tetrakis(dimethyl sulfoxide)dichlororuthenium(II), (toluene)(1,5-cyclooctadiene)ruthenium, triruthenium dodecacarbonyl, tris(2,2′-bipyridyl)ruthenium(II) chloride.

In a further example, the additive gas may comprise hydrogen, where the deposition gas comprises at least one of the ruthenium-containing deposition gases described here.

In a further example, the additive gas may comprise nitrogen, where the deposition gas comprises at least one of the ruthenium-containing deposition gases described here.

In a further example, the additive gas may comprise NH₃, where the deposition gas comprises at least one of the ruthenium-containing deposition gases described here.

In a further example, the additive gas may comprise NO₂, where the deposition gas comprises at least one of the ruthenium-containing deposition gases described here.

In a further example, the additive gas may comprise H₂O, where the deposition gas comprises at least one of the ruthenium-containing deposition gases described here.

In a further example, the additive gas may comprise O₂, where the deposition gas comprises at least one of the ruthenium-containing deposition gases described here.

In one example, the additive gas may comprise oxygen, where the deposition gas comprises at least one of the following rhodium-containing deposition gases:
acetylacetonatobis(ethylene)rhodium(I), chlorobis(ethylene)rhodium(I) dimer, dicarbonyl(2,4-pentanedionato)rhodium(I), di-eta-chloro-tetrakis(phosphorus trifluoride)dirhodium, dirhodium(II) tetrakis(caprolactam), di-μ-chloro-tetracarbonyldirhodium(I), hexarhodium hexadecacarbonyl, hydridotetrakis(triphenylphosphine)rhodium(I), pentaamminechlororhodium(III) dichloride, rhodium octanoate dimer, rhodium(II) acetate dimer, rhodium(II) trifluoroacetate dimer, rhodium(III) acetate, rhodium(III) chloride trihydrate, rhodium(III) chloride, rhodium(III) nitrate (anhydrous), rhodium(III) oxide (anhydrous), rhodium(III) trifluoroacetylacetonate, tetrakis(1,5-cyclooctadiene)tetra-μ-hydridotetrarhodium, tetrarhodium dodecacarbonyl.

In a further example, the additive gas may comprise hydrogen, where the deposition gas comprises at least one of the rhodium-containing deposition gases described here.

In a further example, the additive gas may comprise nitrogen, where the deposition gas comprises at least one of the rhodium-containing deposition gases described here.

In a further example, the additive gas may comprise NH₃, where the deposition gas comprises at least one of the rhodium-containing deposition gases described here.

In a further example, the additive gas may comprise NO₂, where the deposition gas comprises at least one of the rhodium-containing deposition gases described here.

In a further example, the additive gas may comprise H₂O, where the deposition gas comprises at least one of the rhodium-containing deposition gases described here.

In a further example, the additive gas may comprise O₂, where the deposition gas comprises at least one of the rhodium-containing deposition gases described here.

In one example, the etch gases mentioned may be combined with at least one of the additive gases mentioned for the particle beam-induced reaction.

In one example, the etch gas may comprise a halogen, where the additive gas comprises at least one of the following: NH₃, NO₂, H₂O, O₂.

In one example, the etch gas may comprise xenon difluoride, where the additive gas comprises at least oxygen.

In one example, the etch gas may comprise xenon difluoride, where the additive gas comprises at least hydrogen.

In one example, the etch gas may comprise xenon difluoride, where the additive gas comprises at least nitrogen.

In one example, the etch gas may comprise xenon difluoride, where the additive gas comprises at least one of the following: NH₃, NO₂, H₂O, O₂. For example, the following combinations of xenon difluoride and an additive gas may be possible: XeF₂ and H₂O, XeF₂ and O₂, XeF₂ and NH₃, XeF₂ and NO₂.

In one example, the mask may comprise a mask for EUV lithography. In principle, the aspects described herein are alternatively applicable to all lithography masks (for example, including for embossing stamps in nanoimprint lithography, which may also be regarded herein as lithography masks).

In one example, the particle beam may comprise an electron beam. For example, the particle beam may also comprise an ion beam. It is likewise possible that the particle beam comprises an ion beam and an electron beam. A particle beam-induced deposition reaction described herein may comprise, for example, an electron beam-induced deposition (also known by the technical term “focused electron beam induced deposition: FEBID”). A particle beam-induced etch reaction described herein may comprise, for example, an electron beam-induced etching (also known by the technical term “focused electron beam induced etching: FEBIE”).

A second aspect relates to a method of processing a mask for lithography, comprising: providing a gas and a particle beam on the mask for modification of a defect site in a layer sequence of the mask, wherein the layer sequence is adjoined by an imaging structure of the mask and the layer sequence comprises one or more layers. The features and approaches with regard to the first aspect that are described herein may also be employed correspondingly for the second aspect. In particular, the deposition gases, etch gases and/or additive gases mentioned may also be employed for the second aspect. The second aspect fundamentally relates to a modification (e.g., repair) of a defect site in the layer sequence. The second aspect thus also comprises the deposition of an optical grating on the outer layer for repair (and/or of structures as described in DE102017205629A1). This deposition of the optical grating in the second aspect can be effected by the process details of the first aspect that are mentioned herein (for example, with the deposition gases mentioned).

There follows a description of examples of the first aspect, which are also set out correspondingly for better understanding in respect of the second aspect. However, the other examples of the first aspect also correspondingly apply to the second aspect.

In one example of the method of the second aspect, there may be a variance in a thickness of a material of the layer sequence at the defect site.

In one example of the method of the second aspect, a material in the layer sequence may be absent at the defect site.

In one example of the method of the second aspect, there may be a variance in the chemical composition at the defect site.

In one example of the method of the second aspect, there may be a variance in the surface roughness at the defect site.

In one example of the method of the second aspect, the providing of the gas may comprise providing a deposition gas for deposition of deposition material at the defect site. The deposition gases of the first aspect may also be employed for the deposition gases of the second aspect.

In one example of the method of the second aspect, the deposition gas may comprise ruthenium. In one example of the method of the second aspect, the deposition gas may comprise rhodium. In one example of the method of the second aspect, the deposition gas may comprise boron. In one example of the method of the second aspect, the deposition gas may comprise silicon. In one example of the method of the second aspect, the deposition gas may comprise titanium. In one example of the method of the second aspect, the deposition gas may comprise zirconium. In one example of the method of the second aspect, the deposition gas may comprise palladium. In one example of the method of the second aspect, the deposition gas may comprise niobium.

In one example of the method of the second aspect, the providing of the gas may comprise providing an etch gas for removal of material at the defect site. The etch gases of the first aspect may also be employed for the etch gases of the second aspect.

In one example of the method of the second aspect, the providing of the etch gas may cause etching of material in the layer sequence.

In one example of the method of the second aspect, the providing of the etch gas may cause etching of extraneous material at the defect site which is essentially absent at a non-defect site of the layer sequence.

In one example of the method of the second aspect, the etch gas may comprise a halogen. In one example of the method of the second aspect, the halogen may comprise fluorine. In one example of the method of the second aspect, the etch gas may comprise xenon difluoride.

In one example of the method of the second aspect, the layer sequence may comprise one or more outer layers for protection of a reflective layer stack of the mask, where the one or more outer layers comprise the defect site.

In one example of the method of the second aspect, the providing of the gas may further comprise providing of an additive gas. The additive gases of the first aspect may also be employed as additive gases for the second aspect.

In one example of the method of the second aspect, the layer sequence may comprise one or more layers of a reflective layer stack of the mask, where the one or more layers of the reflective layer stack comprise the defect site.

A third aspect relates to a computer program comprising instructions for executing a method of the first and/or second aspect.

A fourth aspect relates to a device for processing of a lithography mask comprising: means of providing a gas and a particle beam on the mask in order to at least partly eliminate any chemical and/or geometric variance of a defect site in a layer sequence of the mask from a target property, wherein the layer sequence is adjoined by an imaging structure of the mask and the layer sequence comprises one or more layers. The device may further comprise a computer system comprising the computer program of the third aspect.

The device may thus be configured to perform a method of the first and/or second aspect.

A further aspect is directed to a method for repairing a defect of a cap layer of a mask for lithography. The method comprises the step of depositing a deposition material on at least a portion of the cap layer and/or a multilayer of the mask. In particular, the deposition material is deposited on the at least a portion of the cap layer and/or a multilayer such that at least the defect of the cap layer is covered by the deposition material.

The cap layer of the mask may comprise a layer adapted to protect at least a portion of the mask. For example, the cap layer may comprise a layer adapted to protect at least a portion of a multilayer stack of the mask. Specifically, the cap layer may be arranged on a first (outermost) layer of the multilayer stack of the mask. In some embodiments, the cap layer may comprise a layer separating the multilayer stack of the mask from an imaging structure of the mask. For example, the cap layer may comprise a single layer. Specifically, the cap layer may comprise a thin layer, e.g., a thickness of the cap layer may be smaller than 10 nm, preferably smaller than 8 nm, more preferably smaller than 6 nm, most preferably smaller than 4 nm.

The defect of the cap layer may comprise a deviation from a target state of the cap layer. The defect may comprise a localized defect, e.g., the deviation from the target state of the cap layer may be spatially restricted. For example, the defect may be spatially restricted in at least two directions, preferably in three directions. In some embodiments, the defect of the cap layer may comprise a defect limited to a portion of the cap layer. For example, the defect of the cap layer may comprise a defect not affecting a structure of the multilayer and/or a structure of the imaging structure of the mask. Specifically, the defect of the cap layer may be spatially limited such as to not extend into the multilayer stack and/or the imaging structure of the mask.

Covering the defect of the cap layer by the deposition material may comprise that the deposition material encloses the defect of the cap layer. In addition, or alternatively, covering the defect of the cap layer by the deposition material may comprise depositing the deposition material such as to place a layer of the deposition material on top of the defect.

Repairing the defect of the cap layer by depositing a deposition material such that at least the defect of the cap layer is covered by the deposition material allows for simple and effective compensation and/or repair of the defect of the mask. In particular, by depositing the deposition material such that at least the defect of the cap layer is covered by the deposition material allows for restoring the protective function of the cap layer, thereby maximizing the stability and/or resistiveness of the mask against chemical and/or mechanical processes, minimizes the risk of damaging the mask during a processing, e.g., a cleaning, of the mask and thus optimizes the lifetime of the mask.

The repair may be implemented such that the optical properties of the mask remain essentially unaffected, i.e., their optical specification is still met.

For example, the deposition material may be deposited such that it comprises a layer of the deposition material. The layer may comprise a thickness similar to that of the (intact) cap layer or smaller. In some examples, it may comprise a thickness smaller than 10 nm, preferably smaller than 8 nm, more preferably smaller than 6 nm, most preferably smaller than 4 nm.

Generally, the defect of the cap layer may comprise a variance in a thickness of the cap layer. In particular, the variance in the thickness may comprise an absence of a cap layer material.

For example, the variance in the thickness of the cap layer may comprise a variance in the thickness of the cap layer compared to a target thickness of the cap layer. In particular, the target thickness of the cap layer may be based on a target state of the mask, e.g., based on a target optical property of the mask. Specifically, the variance in the thickness of the cap layer may comprise a reduced thickness of the cap layer, e.g., a reduced thickness based on a (partial) absence of the cap layer material. For example, the variance in the thickness of the cap layer may comprise a localized, e.g., spatially restricted, variance of the thickness of the cap layer. In particular, a portion of the cap layer, e.g., an area associated with the cap layer, may comprise a variance in the thickness. Specifically, the portion of the cap layer may be thinner than a target thickness of the cap layer. In some embodiments, the defect of the cap layer may comprise an enlarged thickness of the cap layer. In addition, or alternatively, the defect of the cap layer may be associated with a surface roughness of at least a portion of the cap layer (that may be higher than a target surface roughness).

Depositing the deposition material such that at least the defect of the cap layer is covered, wherein the defect of the cap layer may comprise a variance in a thickness of the cap layer, allows for restoring the protective function of the cap layer, thereby maximizing the stability and/or resistiveness of the mask against chemical and/or mechanical processes, may minimize the risk of damaging the mask during a processing, e.g., a cleaning, of the mask and thus optimize the lifetime of the mask.

In addition, or alternatively, the defect of the cap layer may comprise a variance in a chemical composition of the cap layer material. For example, the variance in the chemical composition may be associated with a degradation of a protective function of the cap layer.

For example, the variance in the chemical composition of the cap layer may comprise an unwanted chemical composition of the cap layer, e.g., the variance in the chemical composition of the cap layer as compared to a predetermined chemical target property.

Such variance in the chemical composition may, for example, be caused by a particle beam-induced reaction which may influence chemical properties of the cap layer and/or the mask.

Particularly, the particle beam-induced reaction may penetrate material of the cap layer and may thereby modify the chemical composition thereof.

In general, the defect of the cap layer may be repaired such as to at least partially restore a protective function of the cap layer. Specifically, the defect of the cap layer may be repaired such as to at least partially restore a protective function of the cap layer with respect to the multilayer stack of the mask.

For example, the repairing of the cap layer such as to at least partially restore the protective function may comprise to restore a protective function with respect to a mechanical and/or chemical processing of the mask. For example, the repairing of the cap layer may restore the protective function with respect to particle-beam induced processing of the mask. In particular, the cap layer may be repaired such that the cap layer protects at least a portion of the multilayer stack of the mask.

Repairing the cap layer such as to at least partially restore the protective function of the cap layer maximizes the stability and/or resistiveness of the mask against chemical and/or mechanical processes, minimizes the risk of damaging the mask during a processing, e.g., a cleaning, of the mask and thus optimizes the lifetime of the mask.

In some embodiments, the defect of the cap layer of the mask may be repaired without modifying the multilayer of the mask.

Repairing the defect of the cap layer of the mask without modifying the multilayer and/or multilayer stack of the mask may comprise that a chemical composition and/or an extension and/or layer composition of the multilayer of the mask is essentially unaffected, e.g., invariant, by the repairing of the defect of the cap layer. In particular, repairing the defect of the cap layer of the mask without modifying the multilayer and/or multilayer stack may comprise that no material associated with the multilayer, e.g., material of the layers of the multilayer, is removed during the repairing. In other words, repairing the defect of the cap layer may be such as to only affect the cap layer of the mask, e.g., only affecting the layer comprising the defect. In addition, or alternatively, repairing the defect of the cap layer may be such as to only affect structures arranged above the cap layer, e.g., imaging structures of the mask such as pattern elements.

Repairing the defect of the cap layer of the mask without modifying the multilayer and/or multilayer stack of the mask allows for maintaining the multilayer and/or multilayer stack in an unaltered state, particularly when the state of the multilayer and/or multilayer stack is defect free, e.g., corresponds to a target state of the multilayer and/or multilayer stack. Thus, repairing the defect of the cap layer of the mask without modifying the multilayer and/or multilayer stack enables a specific and selective repair of the mask ensuring that only those parts of the mask are altered that essentially comprise the defect. Therefore, repairing the defect of the cap layer of the mask without modifying the multilayer and/or multilayer stack contributes to a fast, simplified and effective repair of the mask, minimizes the risk of damaging the mask during a processing, e.g., a cleaning, of the mask and thus optimizes the lifetime of the mask.

Generally, a lateral extension of the deposited deposition material may exceed a lateral extension associated with the defect of the cap layer. Specifically, the lateral extension of the deposited deposition material may exceed the lateral extension associated with the defect in two directions. For example, a lateral extension associated with the defect of the cap layer may comprise an area comprising the defect of the cap layer. Specifically, the lateral extension associated with the defect may comprise an area comprising the variance in the thickness of the cap layer and/or the variance in the chemical composition of the cap layer.

Depositing the deposition material such that the lateral extension of deposited material exceeds the lateral extension associated with the defect of the cap layer may comprise that the area comprising the defect is a proper subset of the area covered by the deposition material. In other words, the deposited material may cover the defect of the cap layer as well as a portion of the cap layer not comprising the defect, e.g., a defect-free portion of the cap layer. For example, the defect-free portion of the cap layer may be adjacent to the defect of the cap layer.

Depositing the deposition material such that the lateral extension of deposited material exceeds the lateral extension associated with the defect of the cap layer ensures that the defect is covered by the deposition material and further ensures that the protective function of the repaired cap layer is restored. Thus, depositing the deposition material such that the lateral extension of deposited material exceeds the lateral extension associated with the defect of the cap layer may maximize the stability and/or resistiveness of the mask against chemical and/or mechanical processes, and may minimize the risk of damaging the mask during a processing, e.g., a cleaning, of the mask and thus optimize the lifetime of the mask.

Generally, the lateral extension of the deposited deposition material may be bounded in at least one direction by an imaging structure of the mask. For example, the imaging structure bounding the lateral extension of the deposited deposition material may comprise neighbouring pattern elements of the mask.

For example, the lateral extension of the deposited deposition material may be bounded by a distance, e.g., a lateral distance, between the defect of the cap layer and an imaging structure of the mask. For example, the distance, e.g., the lateral distance, may comprise a distance between a center of the defect of the cap layer and the imaging structure of the mask. In addition, or alternatively, the distance, e.g., the lateral distance, may comprise a distance between a boundary of the defect of the cap layer and the imaging structure. For example, the imaging structure may comprise a pattern element of the mask, e.g., an element extending from the cap layer of the mask. In particular, the distance between the defect and imaging structure may be based on an edge and/or a side face of the pattern element. Generally, the deposition material may be deposited such that the deposition material laterally extends towards the imaging structure, e.g., the pattern clement, of the mask. In some examples, it may be deposited that the deposition material forms a layer that abuts the imaging structure, and/or at least partially extends over the imaging structure.

In some embodiments, the defect may be surrounded and/or encompassed by at least one pattern element, e.g., surrounded and/or encompassed with respect to a first direction. Specifically, the defect may comprise a first extension with respect to the first direction. Similarly, the defect may comprise a second extension with respect to a second direction. In particular, the second direction may comprise a direction essentially perpendicular to the first direction. The first and the second direction may be located within a lateral plane of the mask. In addition, or alternatively, the defect may be surrounded and/or encompassed by at least one pattern elements with respect to the second direction.

For example, the defect may be surrounded and/or encompassed by at least two pattern elements with respect to the first direction and/or surrounded and/or encompassed by at least two pattern elements with respect to the second direction. Specifically, the two pattern elements of the first direction may be located at opposite sides of the defect and/or the two pattern elements of the second direction may be located at opposite sides of the defect. In other words, the two pattern elements of the first direction may be separated by the defect and/or the two pattern elements of the second direction may be separated by the defect. Depositing the deposition material such as to be bounded by the imaging structure may comprise that the deposition material is deposited such as to extend between the two pattern elements of the first direction and/or such as to extend between the two pattern elements of the second direction.

Bounding the lateral extension of the deposited deposition material by an imaging structure of the mask ensures that the defect is covered by the deposition material. In particular, by enlarging the lateral extension of the deposited material such as to be bounded by the imaging structure a homogenous layer within a clear region of the mask can be ensured, thus enhances the optical properties of the mask, e.g., minimizes a deviation between the actual properties of the (repaired) mask and the target optical properties.

In addition, or alternatively, bounding the lateral extension of the deposited deposition material may comprise that no deposition material is deposited within a vicinity of the imaging structure, e.g., within a vicinity of a pattern element of the mask. For example, the vicinity may be such that at a distance of at least 0.5 nm, preferably at least 1 nm, most at least preferably 1.5 nm no deposition material is deposited. Specifically, depositing no deposition material within a vicinity of the imaging structure may comprise that a particle beam associated with the deposition is not directed at the vicinity.

Bounding the lateral extension of the deposited deposition material such that no deposition material is deposited within a vicinity of the imaging structure may ensure that no deposition material is deposited on the imaging structure. Therefore, the (target) optical properties of the mask are maintained even more safely while ensuring the protective function of the cap layer.

In addition, or alternatively, bounding the lateral extension of the deposited deposition material by the imaging structure of the mask may comprise the deposition on at least a portion of the imaging structure of the mask. For example, bounding the lateral extension of the deposited deposition material by the imaging structure of the mask may comprise the deposition of deposition material on neighbouring pattern elements of the mask associated with the defect. In particular, the neighbouring pattern elements may comprise pattern elements surrounding and/or encompassing the defect. Specifically, the deposition of deposition material on the pattern elements may comprise the deposition of deposition material on a top surface of the pattern element, e.g., on the top surface of the highest layer of the pattern element. For example, the deposition material may be deposited such on the pattern element as to form a homogenous layer. In particular, the deposition material may be deposited such as to form a homogenous layer along the top surface of the pattern element.

Depositing the deposition material at least on a portion of the imaging structure of the mask, e.g., on top of the pattern elements located in the neighbourhood of the defect, ensures the deposited deposition material forms a homogenous structure and/or layer along the region defined by the defect and the neighbouring pattern elements. Ensuring that the deposited deposition material forms a homogenous structure and/or layer along the region defined by the defect and the neighbouring pattern elements enhances the realization of targeted optical properties of the mask and contributes to a minimization of negative optical effects that could be caused by inhomogeneities, e.g., local deviations of an intensity and/or local phase shifts.

In general, the method for repairing may further comprise the step of removing at least a portion of an imaging structure of the mask. In particular, the at least a portion of the imaging structure may be located within a vicinity of the defect. For example, the at least a portion of the imaging structure of the mask may comprise at least one pattern element of the mask.

For example, removing at least a portion an imaging structure of the mask may comprise removing at least a portion of an imaging structure of the mask surrounding and/or encompassing the defect of the cap layer. In particular, at least a portion of a pattern element located within a vicinity and/or a neighbourhood of the defect may be removed. Specifically, removing the imaging structure, particularly the pattern element, may be at least partially based on an etching process. For example, the etching process may comprise a particle-beam induced etching process. Specifically, removing at least a portion of the imaging structure may comprise to enlarge a clear region of the mask, particularly a clear region associated with the defect of the cap layer of the mask.

Removing at least a portion of the imaging structure, particularly a pattern element, allows for enlarging a clear region of the mask associated with the defect. In other words, removing at least a portion of the imaging structure, particularly a pattern element, allows for excavating the defect of the cap layer. Excavating the defect of the cap layer contributes to an optimized deposition of the deposition material in a region associated with the defect. In particular, excavating the defect of the cap layer contributes to an optimized flow of a deposition gas to a region associated with the defect of the cap layer, e.g., when the imaging structure comprises a low aspect ratio. An optimized flow of the deposition gas enables a selective and localized deposition of deposition material, thereby contributing to an optimal repair of the defect of the cap layer.

Specifically, the at least a portion of the imaging structure may be removed such as to at least partially expose a portion of the capping layer located beneath the imaging structure, For example, to at least a portion of the imaging structure may be removed such as to expose at least a portion of a surface of the capping layer. Specifically, the at least a portion of the imaging structure may be removed without modifying the cap layer of the mask. For example, removing at least a portion of the imaging structure may comprise removing the imaging structure towering from a portion of the cap layer. In particular, removing at least a portion of the imaging structure may comprise removing a pattern element of the mask towering from a portion of the cap layer of the mask.

Removing the at least a portion of the imaging structure such as to at least partially expose a portion of the cap layer contributed to an enlargement of a clear region of the mask associated with the defect. In particular, exposing a portion of the cap layer allows for creating a homogenous layer within the clear region of the mask associated with the defect. Creating a homogenous layer optimizes a flow of a deposition gas to a region associated with the defect of the cap layer, e.g., when the imaging structure comprises a low aspect ratio. An optimized flow of the deposition gas enables a selective and localized deposition of deposition material, thereby contributing to an optimal repair of the defect of the cap layer.

Generally, depositing the deposition material may comprise depositing the deposition material in a region of the mask associated with the removed imaging structure of the mask.

For example, before the removal of the imaging structure, the imaging structure may tower from the cap layer of the mask. In particular, towering from the cap layer of the mask may comprise an osculation surface, e.g., a region of the cap layer on which the imaging structure in built. After removing of the at least portion of the imaging structure, the osculation surface may be at least partially comprised in a clear region associated with the defect, e.g., a clear region comprising the defect. Depositing the deposition material in a region of the mask associated with the removed imaging structure of the mask may comprise the deposition of deposition material on at least a portion of the osculation surface. In particular, the deposition material may be deposited such as to extend between the defect and the osculation surface. Specifically, the deposition material may be deposited such as to form a continuous layer extending between the defect of the cap layer and the osculation surface. In particular, the continuous layer extending between the defect of the cap layer and the osculation surface may at least partially comprise the defect and/or the osculation surface.

Depositing the deposition material in a region of the mask associated with the removed imaging structure ensures that at least the defect is covered by the deposition material and thus allows for restoring the protective function of the cap layer, thereby maximizing the stability and/or resistiveness of the mask against chemical and/or mechanical processes, minimizes the risk of damaging the mask during a processing, e.g., a cleaning, of the mask and thus optimizes the lifetime of the mask.

In some examples, the method may further comprise the step of reconstructing at least a portion of the removed imaging structure of the mask. For example, the at least a portion of the imaging structure may be reconstructed such as to reconstruct optical properties of the mask.

For example, the (initial) imaging structure of the mask that has been removed may contribute to the optical properties of the mask, e.g., to an intensity and/or phase distribution of the mask. In other words, the (initial) imaging structure of the mask may be designed and/or constructed such as to achieve a target optical property of the mask. Specifically, contributing to the optical properties of the mask may comprise that the (initial) imaging structure of the mask comprises a particular layer sequence and/or a particular material. In addition, or alternatively, contributing to the optical properties of the mask may comprise that the (initial) imaging structure of the mask comprises a particular width and/or height and/or a position with respect to the mask. For example, the (initial) imaging structure of the mask may comprise at least one, preferably at least two, most preferably at least three layers. For example, each layer of the mask may be associated with a respective material. For example, the first layer of the (initial) imaging structure may comprise a first material and the second layer of the (initial) imaging structure may comprise a second material.

Reconstructing at least a portion of the removed imaging structure of the mask may comprise reconstructing and/or rebuilding the (initial) imaging structure, e.g., reconstructing and/or rebuilding the (initial) imaging structure based on the (initial) layer sequence and/or materials and/or width and/or height and/or position. In addition, or alternatively, reconstructing at least a portion of the removed imaging structure of the mask may comprise to at least partially taking into account the deposition of the deposition material. In other words, the deposition of the depositing material may at least partially affect the optical properties of the mask. Generally, reconstructing the at least a portion of the imaging structure may comprise reconstructing the at least a portion of the imaging structure above the deposited deposition material.

Specifically, the at least a portion of the imaging structure of the mask may be reconstructed such as to reconstruct the targeted optical properties of the mask. For example, reconstructing the targeted optical properties of the mask may comprise to at least partially deviate from the (initial) imaging structure of the mask, e.g., reconstructing the imaging element by an altered layer sequence and/or a different material. Specifically, reconstructing the targeted optical properties of the mask may comprise that the imaging structure, e.g., a pattern element of the mask, may be reconstructed and/or rebuilt by an imaging structure comprising one layer, preferably two layers. In particular, a first layer of the reconstructed imaging structure may comprise a first material and a second layer of the reconstructed imaging structure may comprise a second material. In addition, or alternatively, a width and/or a height associated with the first layer of the reconstructed imaging structure may deviate from the width and/or a height associated with the first layer of the (initial) imaging structure. Similarly, a width and/or a height associated with the second layer of the reconstructed imaging structure may deviate from the width and/or a height associated with the second layer of the (initial) imaging structure.

Reconstructing at least a portion of the removed imaging structure of the mask, particularly such as to reconstruct (target) optical properties of the mask, enables a repair of the defect of the cap layer while ensuring that the repaired mask comprises the (target) optical properties.

Specifically, ensuring that the repaired mask comprises the (target) optical properties may comprise a (subsequent) etching of material associated with the reconstruction of the at least a portion of the imaging structure that may have been deposited around the reconstructed at least a portion of the removed imaging structure, e.g., comprising reconstruction material. For example, this etching may be adapted such as to remove excess material (that may, e.g., form a so called “Halo”) which was at least partially generated by reconstructing the imaging structure. In particular, the etching of the reconstruction material may comprise a selective etching. For example, the etching may be selective for the reconstruction material compared to the deposition material, e.g., the material deposited for repairing the cap layer defect.

Generally, the method for repairing may further comprise the step of detecting and/or analyzing the defect of the cap layer. For example, detecting and/or analyzing the defect of the cap layer may be at least partially based on an aerial image of at least a portion of the mask. In addition, or alternatively, detecting and/or analyzing the defect of the cap layer may be at least partially based on an atomic force microscopy image of at least a portion of the mask.

For example, detecting and/or analyzing the defect of the cap layer may comprise detecting a deviation from a target aerial image and/or a target atomic force microscopy image of at least a portion of the mask. In addition, or alternatively, detecting and/or analyzing the defect of the cap layer may comprise determining a variance in a thickness of the cap layer and/or a variance in a chemical composition of the cap layer material and/or an unwanted surface roughness associated with the cap layer. Specifically, detecting and/or analyzing the defect of the cap layer may comprise localizing the variance in the thickness of the cap layer and/or the variance in the chemical composition of the cap layer material and/or the unwanted surface roughness. In particular, the localization may comprise the determination of a position of the defect of the cap layer with respect to the mask and/or the determination of a lateral extension of the defect of the cap layer and/or the determination a depth of the defect of the cap layer.

Detecting and/or analyzing the defect of the cap layer allows for a selective and localized repair of the defect of the cap layer and an adaption of the repair to the actual properties of the defect.

In particular, detecting and/or analyzing the defect of the cap layer enables a specific deposition of the deposition material, thereby ensuring that at least the defect is covered by the deposition material and contributes to the restoring of the protective function of the cap layer. Thus, detecting and/or analyzing the defect of the cap layer maximizes the stability and/or resistiveness of the mask against chemical and/or mechanical processes, minimizes the risk of damaging the mask during a processing, e.g., a cleaning, of the mask and thus optimizes the lifetime of the mask.

In some embodiments, depositing the deposition material may comprise providing a deposition gas and a particle beam on the mask.

Specifically, the deposition gas may comprise ruthenium.

For example, the deposition gas may comprise at least one of the following ruthenium-containing deposition gases:
allylruthenium(II) tricarbonyl bromide, allylruthenium(II) tricarbonyl chloride, benzeneruthenium(II) chloride dimer, bis(2,4-dimethylpentadienyl)ruthenium, bis(cyclopentadienyl)ruthenium(II), bis(ethylcyclopentadienyl)ruthenium(II), carbonylchlorohydridotris(triphenylphosphine)ruthenium(II), chloro(4,4′-dicarboxy-2,2′-bipyridine)(p-cymene)ruthenium(II) chloride, chloro(cyclopentadienyl)bis(triphenylphosphine)ruthenium(II), chloropentaammineruthenium(III) chloride, dicarbonylcyclopentadienylruthenium dimer, dichloro(p-cymene)ruthenium(II) dimer, dichlorotricarbonylruthenium(II) dimer, dichlorotris(triphenylphosphine)ruthenium(II), dihydrotetrakis(triphenylphosphine)ruthenium(II), hexaammineruthenium(III) chloride, (hexamethylbenzene)ruthenium(II) dichloride dimer, (p-cymene)(N,N′-diisopropyl-1,2-ethanediimine)ruthenium, ruthenium pentacarbonyl, ruthenium tetracarbonyl iodide, ruthenium(III) acetylacetonate, ruthenium(III) bromide, ruthenium(III) chloride, ruthenium(III) nitrosylacetate, ruthenium(III) nitrosylchloride monohydrate, ruthenium(III) nitrosylnitrate, ruthenium(III) nitrosylsulfate, ruthenium(IV) sulfide, ruthenium(VIII) oxide, tetraamminechlorohydroxyruthenium(III) chloride, tetrakis(dimethyl sulfoxide)dichlororuthenium(II), (toluene)(1,5-cyclooctadiene)ruthenium, triruthenium dodecacarbonyl, tris(2,2′-bipyridyl)ruthenium(II) chloride.

In addition, or alternatively, the deposition gas may comprise rhodium.

For example, the deposition gas may comprise at least one of the following rhodium-containing deposition gases:
acetylacetonatobis(ethylene)rhodium(I), chlorobis(ethylene)rhodium(I) dimer, dicarbonyl(2,4-pentanedionato)rhodium(I), di-eta-chloro-tetrakis(phosphorus trifluoride)dirhodium, dirhodium(II) tetrakis(caprolactam), di-μ-chloro-tetracarbonyldirhodium(I), hexarhodium hexadecacarbonyl, hydridotetrakis(triphenylphosphine)rhodium(I), pentaamminechlororhodium(III) dichloride, rhodium octanoate dimer, rhodium(II) acetate dimer, rhodium(II) trifluoroacetate dimer, rhodium(III) acetate, rhodium(III) chloride trihydrate, rhodium(III) chloride, rhodium(III) nitrate (anhydrous), rhodium(III) oxide (anhydrous), rhodium(III) trifluoroacetylacetonate, tetrakis(1,5-cyclooctadiene)tetra-μ-hydridotetrarhodium, tetrarhodium dodecacarbonyl.

In addition, or alternatively, the deposition gas may comprise boron. In addition, or alternatively, the deposition gas may comprise silicon. In addition, or alternatively, the deposition gas may comprise titanium. In addition, or alternatively, the deposition gas may comprise zirconium. In addition, or alternatively, the deposition gas may comprise palladium. In addition, or alternatively, the deposition gas may comprise niobium.

A further aspect relates to a device for repairing a defect of a cap layer of a mask for lithography. The device comprises means for obtaining a characterization of the defect of the cap layer of the mask. In addition, the device comprises means for automatically depositing a deposition material on at least a portion of the cap layer and/or a multilayer of the mask. In particular, the means for automatically depositing is adapted such that at least the defect of the cap layer is covered by the deposition material.

For example, the device may comprise a scanning electron microscope (SEM) and/or a scanning probe microscope, e.g., a scanning probe microscope in the form of an atomic force microscope. Specifically, the SEM may comprise an electron gun. In addition, or alternatively, the SEM may comprise a column in which electron optics and/or beam optics may be arranged. For example, the electron gun may be adapted to produce an electron beam. In addition, the electron optics may be adapted to focus the electron beam, e.g., directing the electron beam to a desired output on the mask. In addition, or alternatively, the device may comprise a specimen stage. For example, the specimen stage may be movable in at least one, preferably at least two, most preferably at least three spatial directions in relation to the electron beam of the SEM. For example, the specimen stage may be adapted to receive the mask, e.g., an EUV mask.

In addition, or alternatively, the device may comprise a detector for detecting secondary electrons or backscattered electrons produced at a measurement point by an incident electron beam. For example, the detector may be controlled by a control device. In addition, the control device may be adapted to receive measurement data of the detector. Specifically, the control device may be adapted to generate images from the measurement data. Generally, the device may additionally comprise a detector for detecting the photons produced by the incident electron beam. For example, the detector may be adapted such as to spectrally resolve the energy spectrum of the generated photons, thereby allow conclusions to be drawn concerning the composition of the surface or layers near the surface of the mask.

In addition, or alternatively, the device may comprise an ion source, which may be adapted to provide low-energy ions in the region of the measurement point, e.g., in order to prevent the mask and/or a surface of the mask from having a negative or positive surface charge. In particular, with the aid of an ion source, it may be possible to reduce a negative or positive charge of the mask, e.g., in a local and controlled fashion, and hence preventing a reduction in a lateral spatial resolution of the electron beam. In addition, or alternatively, the device may comprise a scanning probe microscope in form of an atomic force microscope (AFM).

Specifically, the means for obtaining may comprise an interface adapted to receive an aerial image of at least a portion of the mask comprising the defect.

For example, the means for obtaining may comprise a computer (system) capable of ascertaining an image of the surface of the cap layer, e.g., based on measurement data obtained from the AFM. For example, the system may comprise an aerial image system and/or an exposure system for photolithographic masks. Specifically, the computer system may be able to receive measurement data of a focus stack of aerial image measurements or measurements containing a tuning of an aerial image system through the focus of the mask.

In addition, or alternatively, the means for obtaining may comprise an interface adapted to receive an atomic force microscopy image of at least a portion of the mask comprising the defect.

Generally, the device may further comprise means for determining a repair shape and/or a repair workflow for the mask, at least partially based on the characterization of the defect of the cap layer.

Whether aspects or functions of the device are implemented as hardware or software depends upon the particular application and design constraints imposed on the overall system. By way of example, an element, or any portion of an element, or any combination of elements may be implemented as a processing system that may include one or more processors. Examples of processors include microprocessors, microcontrollers, graphics processing units (GPUs), central processing units (CPUs), application processors, digital signal processors (DSPs), reduced instruction set computing (RISC) processors, systems on a chip (SoC), baseband processors, field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software shall be construed broadly to mean instructions, instruction sets, code, code segments, program code, programs, subprograms, software components, applications, software applications, software packages, routines, subroutines, objects, executables, threads of execution, procedures, functions, etc., whether referred to as software, firmware, middleware, microcode, hardware description language, or otherwise.

Accordingly, in one or more exemplary embodiments, the functions described may be implemented in hardware, software, or any combination thereof. If implemented in software, the functions may be stored on or encoded as one or more instructions or code on a computer-readable medium. Computer-readable media includes computer storage media. Storage media may be any available media that can be accessed by a computer. By way of example, and not limitation, such computer-readable media can comprise a random-access memory (RAM), a read-only memory (ROM), an electrically erasable programmable ROM (EEPROM), optical disk storage, magnetic disk storage, other magnetic storage devices, combinations of the aforementioned types of computer-readable media, or any other medium that can be used to store computer executable code in the form of instructions or data structures that can be accessed by a computer.

It is noted that any combination of features that have been described above as belonging to certain embodiments/aspects of the present invention is also an embodiment of the present invention, provided such a feature combination is feasible, i.e., does not lead to any contradictions.

### DESCRIPTION OF DRAWINGS

The detailed description that follows describes technical background information and exemplary embodiments of the invention with reference to the figures, which show the following:

FIG. 1 is a schematic illustration, in a side view, of a mask for EUV lithography that does not have a defect site.

FIG. 2 is a schematic illustration, in a side view, of a defective mask for EUV lithography where material of the outer layer of the mask is partly absent.

FIG. 3 is a schematic illustration, in a side view, of a defective mask for EUV lithography where material of the outer layer of the mask is completely absent, such that the reflective layer stack of the mask is exposed.

FIG. 4 is a schematic illustration, in a side view, of a defective mask for EUV lithography where material of the outer layer has a chemically unwanted property.

FIG. 5 is a schematic illustration, in a side view, of a defective mask for EUV lithography where material of the outer layer partly has a chemically unwanted property.

FIG. 6 is a schematic illustration, in a side view, of a defective mask for EUV lithography where excess material is present at the defect site.

FIG. 7 is a schematic illustration, in a side view, of a defective mask for EUV lithography where there is an unwanted surface roughness at the defect site.

FIG. 8 is a schematic illustration, in a side view, of a defective mask for EUV lithography where material of the outer layer and of the reflective layer stack of the mask is absent.

FIG. 9 is a schematic illustration, in a side view, of a defective mask for EUV lithography where material of the reflective layer stack of the mask has a chemically unwanted property.

FIGS. 10A-10E show, in a schematic side view, further examples of masks for lithography without reflective layer stack, where the masks in FIGS. 10B-10E have defect sites.

FIGS. 11A-11D show, in a schematic side view, an exemplary workflow of a repair of the cap layer according to aspects of the present invention.

FIG. 12A is a schematic illustration, in a side view, of a repaired defect in a cap layer of a mask, wherein the deposited deposition material extends between two pattern elements without covering the pattern elements.

FIG. 12B is a schematic illustration, in a side view of a repaired defect in a cap layer of a mask, wherein the deposited deposition material extends between two pattern elements and covers the pattern elements.

### DETAILED DESCRIPTION

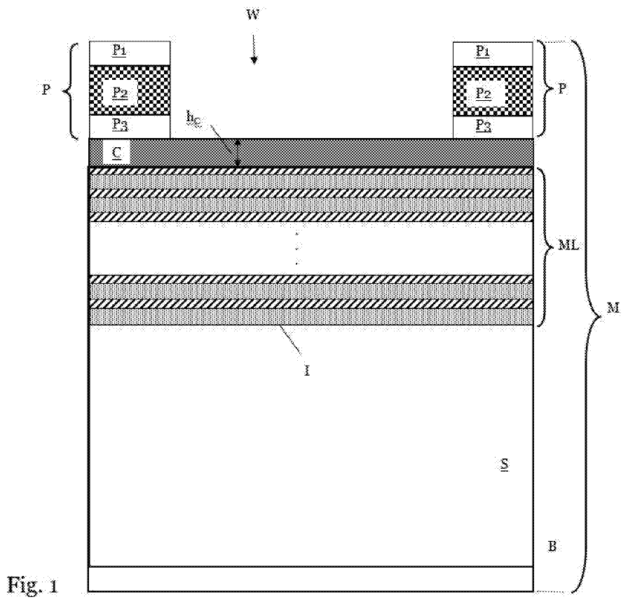

FIG. 1 is a schematic illustration, in a side view, of a mask for EUV lithography that does not have a defect site. Such a mask M may also be referred to as an EUV mask. As mentioned, the technical teaching described herein may alternatively be applied correspondingly to any masks for lithography. For example, the technical teaching may also be applied to masks for UV lithography, DUV lithography, x-ray lithography, and for nanoimprint stamps for nanoimprinting lithography.

The EUV mask M in FIG. 1 may comprise a substrate S. In addition, the EUV mask may comprise a reflective layer stack ML. The reflective layer stack ML may comprise one or more reflective layers. These may be in an alternating arrangement so as to form a Bragg mirror. The reflective layer stack ML may be configured to reflect light which is used for EUV lithography. Typically, the exposure wavelength in UV lithography may be 13.5 nm. For example, the reflective layer stack may therefore have a reflective effect for an exposure wavelength of 13.5 nm.

In one example, the reflective layer stack ML may adjoin the substrate S, such that there is an interface I between the reflective layer stack ML and the substrate S.

The EUV mask M may comprise an outer layer C. The outer layer C may adjoin the reflective layer stack ML. FIG. 1 shows, in schematic form, the height ho of the outer layer C. The height ho of the outer layer C is defined here via the normal vector to the surface plane of the EUV mask M. The outer layer C may serve for mechanical and/or chemical protection of the reflective layer stack. The outer layer C may comprise, for example, ruthenium and/or rhodium. In addition, the outer layer C may also comprise two or more partial outer layers.

The EUV mask M may comprise one or more imaging structures P. An imaging structure P may be configured to absorb an exposure wavelength for EUV lithography. It is likewise possible for an imaging structure P to be configured to cause a phase shift in the exposure wavelength for EUV lithography. The EUV mask may thus also comprise a phase-shifting EUV mask. In summary, the one or more imaging structures P on the reflective layer stack ML may be designed such that a lithography image with a defined pattern can be created in the case of lithography in a target plane. In the example of FIG. 1, the imaging structures comprise three layers P1, P2, P3. However, the present disclosure is not limited to EUV masks, the imaging structures of which comprise three layers. An EUV mask may also comprise, for example, imaging structures formed from one layer (or two layers).

The EUV mask M may comprise a backside layer B. The backside B may adjoin the substrate S. The backside B may, for example, be electrically conductive in order to enable suitable mounting of the EUV mask M.

In EUV lithography, the EUV mask M may be irradiated with light W to create the lithographic image. In lithography, the light W is incident on the front side of the EUV mask M on which the imaging structures P are mounted. The light W, according to the mask design, may be at least partly absorbed in the imaging structures P. In addition, the light W may enter the reflective layer stack ML via the exposed outer layer C. Since the reflective layer stack acts like a mirror (e.g., a Bragg mirror), the light W is then reflected by the EUV mask M. The reflective layer stack ML thus ensures that the incident light W that has not been absorbed by an imaging structure is reflected by the EUV mask. By virtue of this mechanism, it is possible to create a wide variety of different lithography images. The reflection characteristics of the EUV mask M are influenced by the material properties of the reflective layer stack ML and the material properties of the outer layer C. Thus, if there is a defect in the outer layer C and/or in the reflective layer stack ML, the quality of the lithography image may be adversely affected. It is likewise possible for a defect in the region of the outer layer C and/or in the region of the reflective layer stack ML to reduce the lifetime of the EUV mask M. This is because EUV masks M are subject to high physical and chemical influences, where defects in the outer layer and/or in the reflective layer stack can lead to premature wear of the EUV mask M. For example, a defect in the outer layer C can thus impair the protective function thereof for protection of the reflective layer stack ML, such that the underlying reflective layer stack ML is more easily attacked. It is likewise possible for a defect in the reflective layer stack to become more critical over time, and prematurely reduce the lifetime of the EUV mask.

Presented hereinafter are various types of defective EUV masks that can be corrected by the methods described herein.

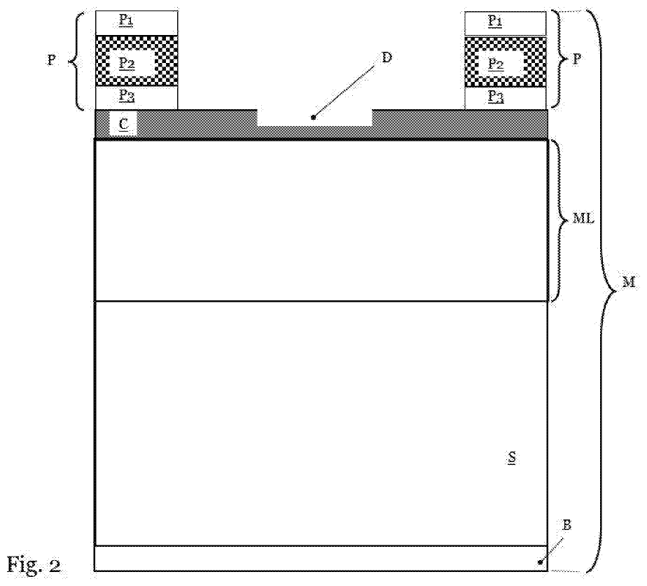

FIG. 2 is a schematic illustration, in a side view, of a defective mask for EUV lithography where material of the outer layer C of the mask is partly absent locally. Thus, the material of the outer layer C is absent at the defect site D. However, the material of the outer layer still covers the reflective layer stack ML at the defect site D.

The absent material of the outer layer C may, for example, have such dimension that the optical properties of the EUV mask are no longer correct. It is likewise possible by virtue of the absent material for the protective function of the outer layer C to no longer be reliably assured.

Such a defect can be repaired by the methods described herein. As described herein, it is possible via particle beam-induced deposition at the defect site D to correct (and, for example, replenish) the absent material in the outer layer C. The outer layer C is thus repaired by the method described herein.

This repair can at least locally assure the protection of the reflective layer stack ML at the repaired site and the optical properties of the EUV mask. The deposition material may be configured such that it has sufficiently low absorption of light for a wavelength of 13.5 nm and/or a sufficiently small phase shift for a wavelength of 13.5 nm. In addition, the deposition material may be configured such that it has sufficiently high cleaning stability. Masks are thus subject to frequent cleaning, where the masks are exposed to chemical and/or physical influences in the course of cleaning. Resistance to these influences may be considered for the deposition material. The deposition material may likewise be configured such that it has sufficiently high irradiation stability. Masks may thus be subject to high chemical and/or physical influences on lithographic irradiation (for example, a hydrogen plasma may be generated in EUV lithography). Resistance to these influences may be considered for the deposition material.

The repair can simultaneously also ensure that the optical properties of the EUV mask M at the defect site are in spec, e.g., the deposition of deposition material at the defect site may be such as to reconstruct the optical properties of the mask sufficiently well. Reconstructing the optical properties of the mask sufficiently well may comprise that the optical properties of the (reconstructed) mask are such that the (reconstructed) mask can be used within a lithographic production workflow (and essentially correspond to the optical properties at a non-defect site).

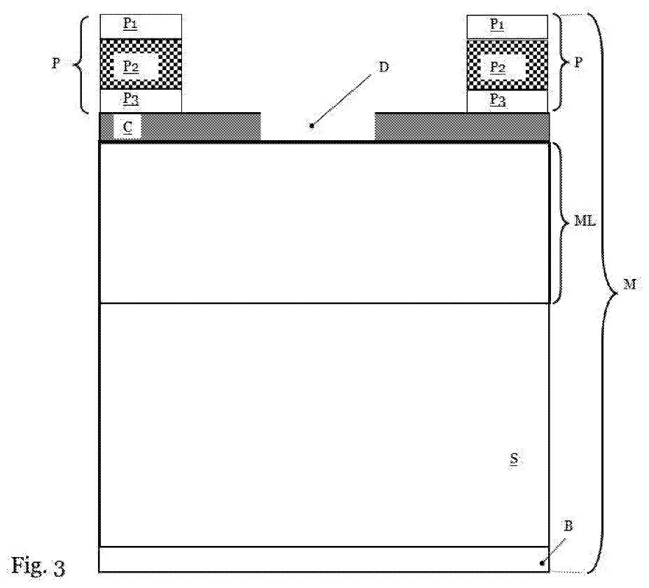

FIG. 3 is a schematic illustration, in a side view, of a defective mask for EUV lithography where material of the outer layer of the mask is completely absent locally, such that the reflective layer stack of the mask is exposed. The defect site D in FIG. 3 can likewise be repaired as described herein and also shown for the defect site D in FIG. 2.

In the repair of the outer layer C by use of deposition, it is possible to determine the thickness (or height) of the deposition material. For example, this may be effected based on a signal from backscattered electrons. This analysis can be effected in the course of deposition or after a deposition step. It is likewise conceivable that the thickness of the deposition material is determined after deposition via an atomic force microscopy measurement.

As described herein, the deposition material may include ruthenium and/or rhodium.

As likewise described, the deposition material may also comprise at least one of the following: B, BN, B₄C, SiO₂, SiC, Si₃N₄, TiO₂, TiN, ZrO₂, Pd, Nb.

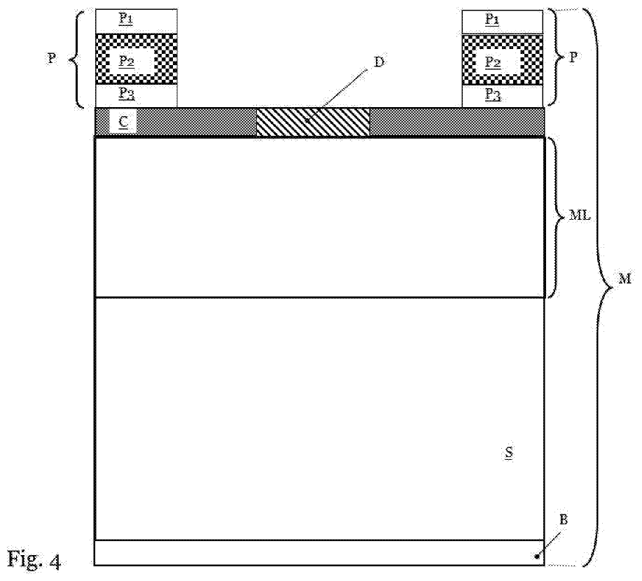

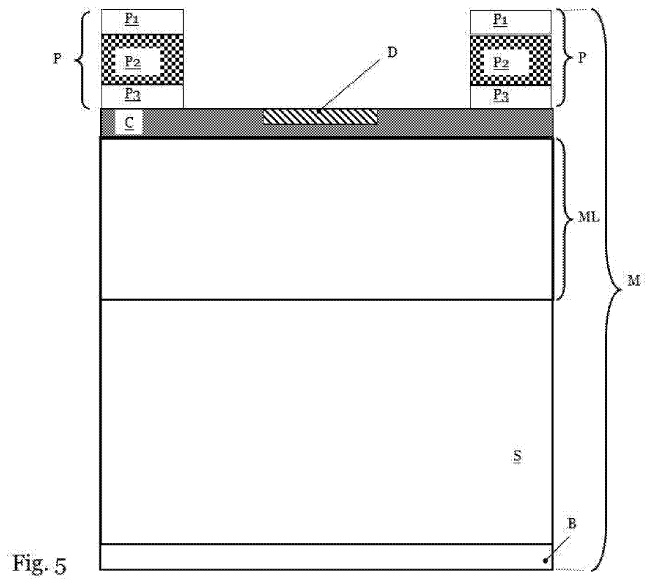

FIG. 4 is a schematic illustration, in a side view, of a defective mask for EUV lithography where material of the outer layer at a defect site has an unwanted chemical property. For example, there may be an unwanted chemical composition of the material of the outer layer C at the defect site D. In the example of FIG. 5, the unwanted chemical property is present locally across the entire height of the outer layer C.

As described herein, in such a case, a two-stage method may be employed. First of all, the material having the unwanted chemical property may be removed via particle beam-induced etching until the reflective layer stack ML is exposed. On etching, it is possible to establish a selectivity with respect to the adjoining reflective layer stack ML, such that the latter is essentially not etched (for example, via suitable additive gases as described herein). After this etching, the defined defect exists that material is locally completely absent at the defect site (as shown for FIG. 3). This defined defect or state can then be corrected via particle beam-induced deposition as described herein. The gap created can thus be filled by a deposition material.

FIG. 5 is a schematic illustration, in a side view, of a defective mask for EUV lithography where material of the outer layer at a defect site has an unwanted chemical property. For example, there may likewise be an unwanted chemical composition of the material of the outer layer C at the defect site D (as in FIG. 4). In the example of FIG. 5, the unwanted chemical property, however, is present only locally across part of the overall height of the outer layer C.

This type of defect may also be corrected as described for FIG. 4 (for example, by a two-stage method). There may thus likewise be etching at the defect site until the reflective layer stack is exposed. What is thus removed in this example is material of the outer layer C having a chemically unwanted property and the underlying material of the outer layer C with a non-faulty property. The defined defect which is then created that material is absent at the defect site can be corrected via an appropriate deposition. The gap created can thus be filled by a deposition material.

It is likewise conceivable for there to be an etching operation that removes (essentially) only the material of the outer layer C having the chemically unwanted property, such that no material of the layer stack is exposed. Subsequently, the defined defect exists that material is partly absent at the defect site (as shown for FIG. 2). This can then be corrected via particle beam-induced deposition as described herein. The gap created can thus be filled by a deposition material.

In a further example, material in the outer layer C having an unwanted property can also be removed by an etching operation that essentially does not alter the geometry of the defect site. The defect site D with the unwanted chemical property which is shown in FIGS. 4 and 5 may, for example, be a region in which there are disruptive intercalated substances (or elements).

These disruptive substances can be removed from the outer layer by a suitable particle beam-induced etching reaction.

For example, the intercalated substances may comprise disruptive oxygen atoms (although other extraneous substances are also conceivable). In order to remove these from the outer layer, as well as the particle beam and the etch gas, it is possible to provide an additive gas as reducing agent. The oxygen atoms can enter into a reaction with the reducing agent, such that these are removed from the material, while the geometry of the material can essentially be conserved. For example, the additive gas may comprise ammonia (NH₃). This can enter into a reaction with the intercalated oxygen atoms, so as to form NO₂, for example, which can then diffuse out of the outer layer C. It is thus possible to remove disruptive oxygen from the outer layer. The presence of the disrupted intercalated substances can be determined, for example, via an electron image, the signal of which is based on electrons that are scattered back from a material depth. This analysis can likewise be used for verification of the repair made with the reducing agent.

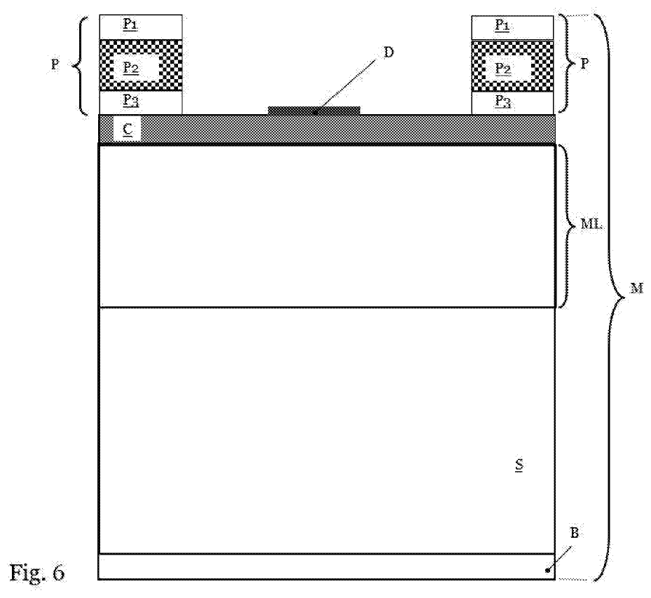

FIG. 6 is a schematic illustration, in a side view, of a defective mask for EUV lithography where excess material is present at the defect site. In one example, the excess material at the defect site D may be extraneous material that has added onto the surface of the outer layer.

The extraneous material added on may be removed via particle beam-induced etching (as described herein). This can be effected, for example, with a selectivity with respect to the material of the outer layer C. In the etching of the extraneous material added on, there may be unwanted etching of the outer layer C. Therefore, a gap may thus have been created within the outer layer C. This again constitutes the defined defect of the absent material (as detailed for FIGS. 2 and 3). Correspondingly, this can be corrected via particle beam-induced deposition (as described herein).

For example, the extraneous material added on may comprise oxygen and/or carbon. In such a case, it is possible to make use of a fluorine-based etch gas in the particle beam-induced etch reaction (e.g., xenon difluoride, XeF₂).

In a further example, the excess material shown in FIG. 6 at the defect site D may also constitute an excess height of the thickness (or height) of the outer layer C. This type of excess material may also be corrected via an etching operation. For this purpose, for example, the material at the defect site D may be removed such that the elevation is essentially levelled out by comparison with the surface of the surrounding non-defect sites of the outer layer C. It is likewise conceivable that, in the case of such a defect, the material at the defect site D is locally completely removed until the reflective layer stack is exposed (as shown for FIG. 3). Subsequently, this defined state can be corrected again via a deposition (as described herein).

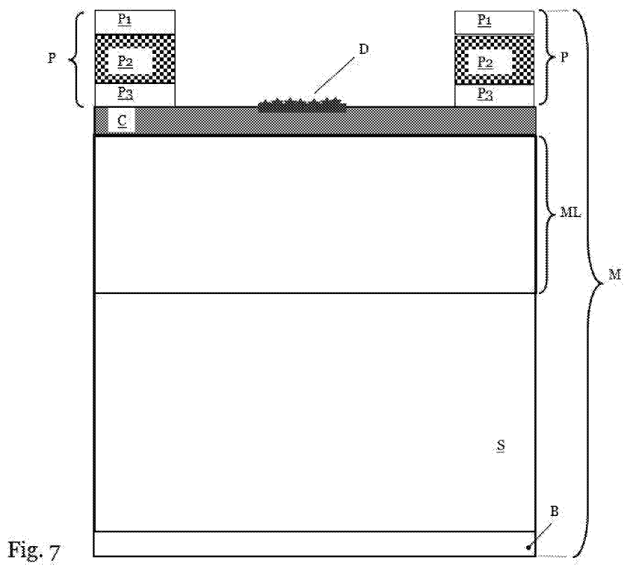

FIG. 7 is a schematic illustration, in a side view, of a defective mask for EUV lithography where there is an unwanted surface roughness at the defect site by comparison with a non-defect site.

In one example, it is possible to deposit a deposition material on the site with the unwanted surface roughness via a particle beam-induced deposition reaction. The deposition material may be configured such that the variance in the surface roughness from the target property is at least partly eliminated. It is likewise possible to configure the deposition material such that the protection by the reflective layer stack ML at the repair site, and also the optical properties of the EUV mask, are at least locally assured (as described herein). For example, it is possible to deposit a thin layer of a deposition material over the defect site D with the unwanted surface roughness, such that a desired change in the surface roughness occurs.

In one example, etching via a particle beam-induced etching reaction may take place above the site with the unwanted surface roughness. The etching may be configured such that the variance in the surface roughness from the target property is at least partly eliminated. It is likewise possible to configure the etching such that the protection by the reflective layer stack ML at the repair site, and also the optical properties of the EUV mask, are at least locally assured (as described herein). For example, slight etching is possible over the defect site D with the unwanted surface roughness, such that a desired change in the surface roughness occurs.

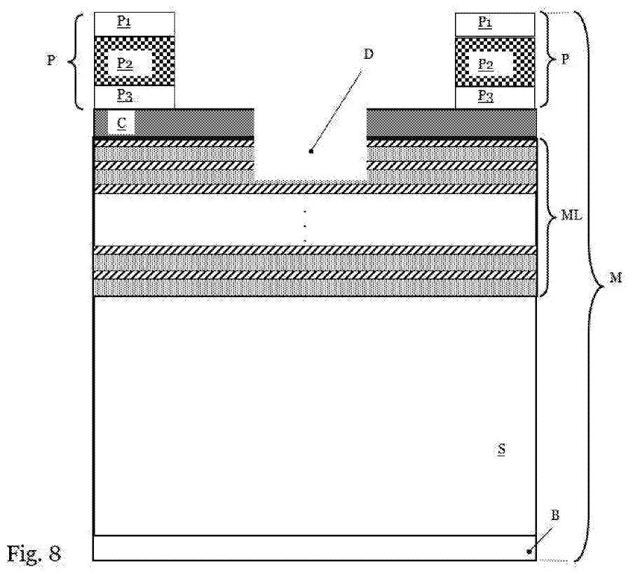

FIG. 8 is a schematic illustration, in a side view, of a defective mask for EUV lithography where material of the outer layer and of the reflective layer stack of the mask is absent. In this case, one or more particle beam-induced deposition reactions may be undertaken in order to replenish the absent material of the reflective layer stack ML and the absent material of the outer layer C.

FIG. 8 shows, by way of example, layers of the reflective layer stack ML, where the material thereof is absent at the defect site D. In one example, the layers of the reflective layer stack may comprise silicon and/or molybdenum. In such a case, a deposition material may be created at the defect site that comprises silicon and/or molybdenum, in order to correct the absent material in the multilayer stack. For a deposition material comprising silicon, it is possible to choose a deposition gas comprising silicon in the particle beam-induced reaction (as indicated herein). For example, the deposition gas comprising silicon may comprise tetraisocyanatosilane. In another example, the deposition gas comprising silicon may comprise tetraethyl orthosilicate (TEOS).

Generally, for a deposition material comprising molybdenum, it may be possible to choose a deposition gas comprising molybdenum. For example, for a deposition gas comprising molybdenum, it may be possible to use a carbonyl comprising molybdenum. Particularly, a deposition gas comprising molybdenum may comprise a gas comprising molybdenum hexacarbonyl (Mo(CO)₆).

For correction of the absent material in the reflective layer stack ML, it is also possible to make use of deposition material that does not necessarily include silicon or molybdenum. For instance, it is also possible to make use of all the other deposition gases described herein (electively in combination with additive gases) in order to create deposition material that corrects absent material in the reflective layer stack ML.

In order to correct the absent material in the outer layer C in the example of FIG. 8, it is possible to make use of the operations already described herein for repair of the outer layer C.

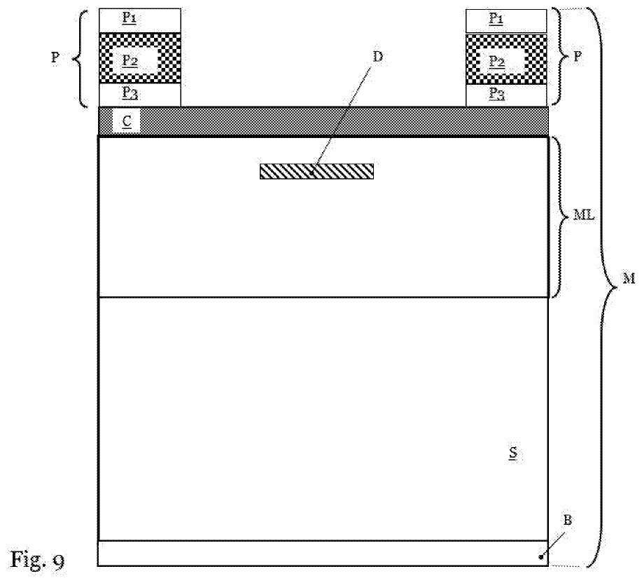

FIG. 9 is a schematic illustration, in a side view, of a defective mask for EUV lithography where material of the reflective layer stack of the mask has a chemically unwanted property. For example, there may be an unwanted chemical composition at the defect site D in the reflective layer stack ML that does not exist at a non-defect site within the reflective layer stack.

In the case of such a defect, the optical properties no longer correspond to those originally envisaged (for example, there may be too high or low absorption of light at a wavelength of 13.5 nm). It is likewise possible in the case of such a defect for the volume of the reflective layer stack ML to increase locally significantly, which can result in bulges and/or mechanical stresses in the outer layer C. As a result, this can break up over time (possibly also in combination with mask cleaning), and so there is an elevated risk that the reflective layer stack ML is no longer protected from changes in the course of further use of the mask. Such a defect within the reflective layer stack should therefore be corrected.

However, this defect site D in the example of FIG. 9 is not easily accessible since the defect site D is within the reflective layer stack ML. There is thus also non-defective material of the reflective layer stack ML above the defect site D; there is likewise non-defective material of the outer layer C above the defect site D.

One approach is therefore to expose the defect site within the reflective layer stack via particle beam-induced etching processes. First of all, for this purpose, a portion of the outer layer C above the defect site D may be removed. For this purpose, it is possible to use a particle beam-induced etch reaction with a corresponding etch gas (as described herein). Subsequently, non-defective material of the reflective layer stack ML above the defect site D may be removed until the material of the defect site D is accessible to the particle beam-induced etch reaction. It is thus then also possible to correct the material of the defect site D within the reflective layer stack ML via a particle beam-induced etch reaction. For example, the material having the unwanted (chemical and/or geometric) property at the defect site D may be removed via a particle beam-induced etching operation.

After successful removal of this defect site D, the defect is present as described for FIG. 8. Thus, there then exists the defined state that material of the outer layer C and material of the reflective layer stack ML of the mask is absent. This defect may, as described for FIG. 8, be corrected via one or more particle beam-induced deposition reactions, which replenishes the absent material with appropriate repair material.

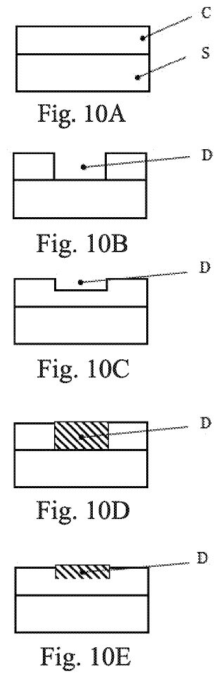

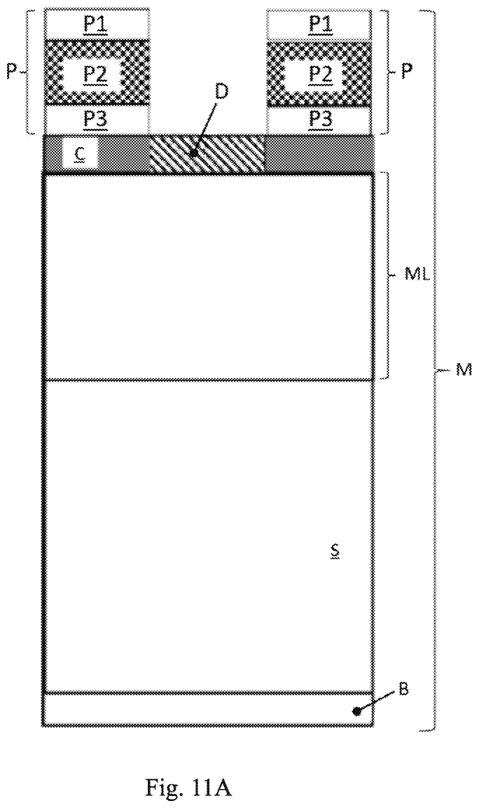

FIG. 10A)-10E) show, in a schematic side view, further examples of masks for lithography, where the masks in FIG. 10B)-10E) have defect sites. These examples are not reflective masks. In the case of such masks, there is no reflective layer stack as described herein for the EUV masks. FIG. 10A) shows a schematic of a structure of a non-defective mask without a reflective layer stack. In the case of such masks, there may also be at least one outer layer C that likewise fulfils a protective function for underlying layers of the mask. It is likewise possible to mount imaging structures on this at least one outer layer C, which are not shown here. In one example, the outer layer C adjoins a substrate S of the mask. It should be noted that, in other examples, there may also be one or more further layers between the protective layer C and the substrate S, although they are not detailed, in order to bring about significant reflectivity for the exposure wavelength in lithography. For example, these masks may be transmissive masks for lithography. In the case of transmissive masks, exposure is effected from the side of the outer layer C (on which the imaging structures are also mounted), where the light exits on the opposite side of the mask (on the substrate side), which is then used for lithographic imaging. It is also possible for such masks to have the faults described herein in the at least one outer layer. These faults may also be corrected by the approaches described herein.

Reference is therefore made briefly below to illustrative error patterns in the outer layers of these masks without reflective layer stack, where the teaching described herein can likewise be employed for the correction thereof.

FIG. 10B) shows a defective mask (without reflective layer stack) where there is a complete lack of material of an outer layer C locally at the defect site D thereof, such that an underlying substrate layer S is exposed.

FIG. 10C) shows a defective mask (without reflective layer stack) where there is a partial lack of material of an outer layer C at the defect site D thereof, such that an underlying substrate layer S is not yet exposed.

FIG. 10D) shows a defective mask (without reflective layer stack) where there is an unwanted chemical property over the entire height of an outer layer C at the defect site D thereof.

FIG. 10E) shows a defective mask (without reflective layer stack) where there is an unwanted chemical property over part of the height of an outer layer C at the defect site D thereof.

It is likewise possible in such masks for there to be defect sites where there is an unwanted surface roughness on the outer layer.

In addition, in the case of such masks, there may be defect sites where the outer layer has excess material. For example, even in the case of masks without a reflective layer stack, there may be extraneous material added onto the outer layer. It is likewise possible in the case of such masks for an outer layer to have at a local site an excess thickness (for example, an elevation) by comparison with the surrounding non-defective surface of the outer layer.

A device for implementation of the methods described herein may, for example, be a mask repair device that has been configured for these methods. An illustrative device may comprise, for example, a scanning electron microscope (SEM) for provision of a particle beam, which, in this example, is an electron beam. An electron gun can generate the electron beam, which can be directed by one or more beam-forming elements as a focussed electron beam onto a lithography mask, which is disposed on a sample stage (or stage, chuck). In addition, the scanning electron microscope can be used to control parameters/properties of the electron beam (e.g., acceleration voltage, dwell time, current, focusing, spot size, etc.) The electron beam may serve as an energy source for initiating a local chemical reaction in a working region of the lithography mask. This may be utilized, for example, for the methods described herein (for example, for the implementation of the electron beam-induced etching or electron beam-induced deposition). In addition, the electron beam may be utilized for capturing an image of the lithography mask. For this purpose, the device may comprise one or more detectors for detecting electrons (for example, secondary electrons, backscattered electrons).

In order to conduct the corresponding methods specified herein, the illustrative device may have one or more reservoir vessels for the deposition gases and/or etch gases. For example, a first reservoir vessel may store a deposition gas. A second reservoir vessel may store an etch gas. In some examples, the temperatures of the reservoir vessels may be controlled independently of one another. In addition, there may also be reservoir vessels for one or more additive gases. In addition, in the illustrative device, each reservoir vessel has its own gas inlet system, which can end with a nozzle close to the point of incidence of the electron beam on the lithography mask.

Each reservoir vessel may have its own control valve in order to control the amount of the corresponding gas provided per unit time, i.e., the gas volume flow rate of the corresponding gas. This can be effected in such a way that the gas volume flow rate is controlled at the point of incidence of the electron beam. The device may include a pump system for generating and for maintaining a pressure required in the process chamber, The device may also comprise a control unit (or closed-loop control unit) which may, for example, be part of a computer system. The device, in one example, may be configured such that the computer system and/or the control unit controls the process parameters of the methods disclosed herein. This configuration can enable controlled or automated implementation of the methods according to the invention as specified herein, for example, without manual interventions. This configuration of the device can be achieved or enabled, for example, via the computer program according to the invention as described herein.

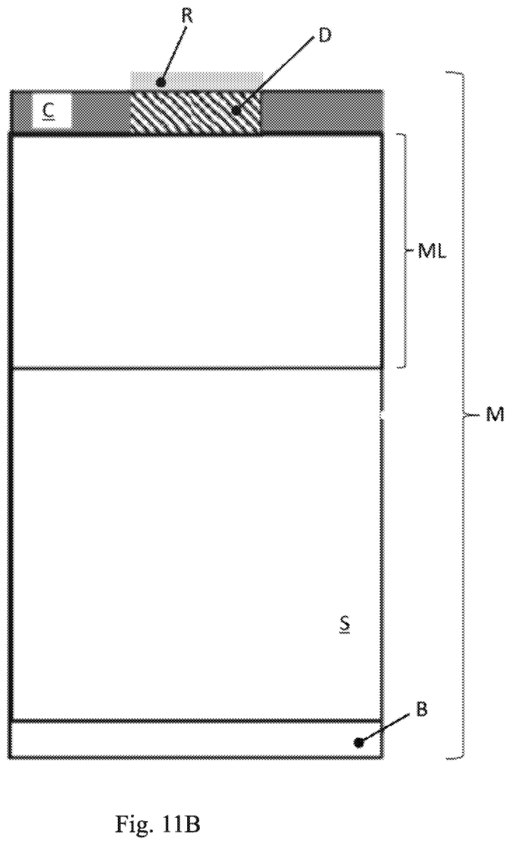

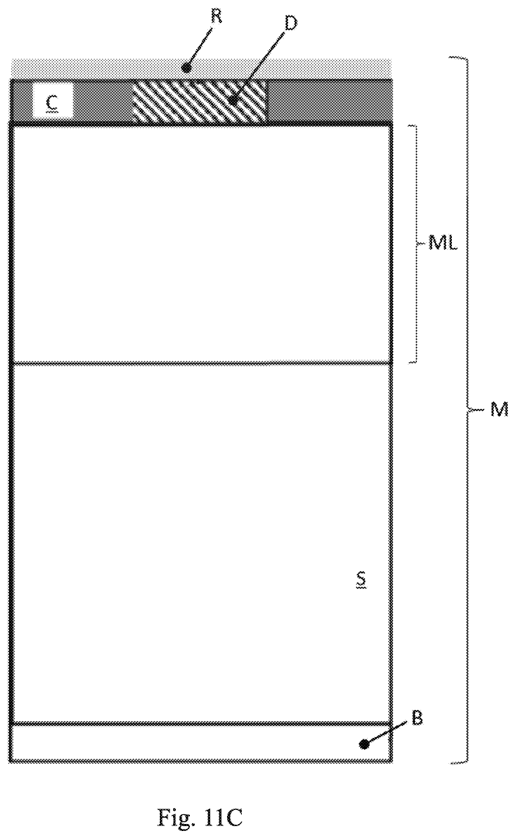

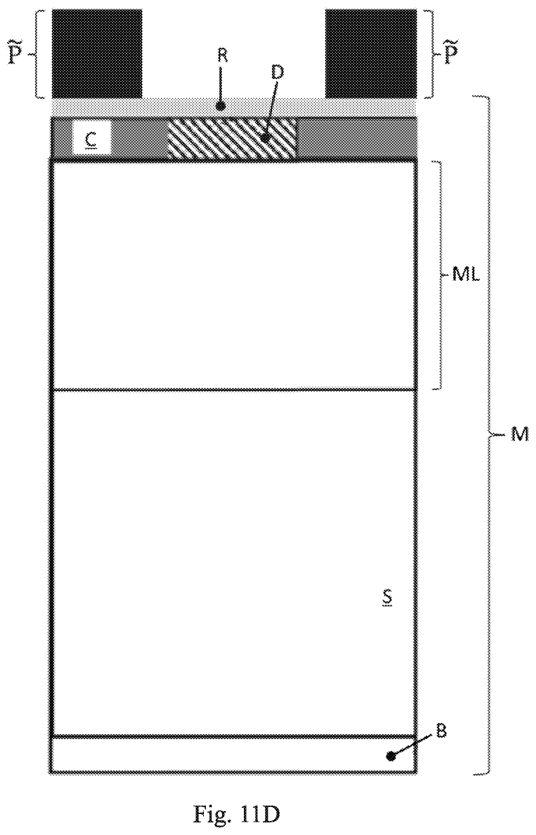

FIGS. 11A to 11D illustrate an exemplary workflow for a repair of a defect of a cap layer of a mask according to certain aspects. The mask M in FIGS. 11A to 11D may comprise a substrate S. Specifically, it may be an EUV mask. The EUV mask may comprise a reflective (multi-) layer stack ML. The reflective layer stack ML may comprise one or more reflective layers. These may be in an alternating arrangement so as to form a Bragg mirror. The reflective layer stack ML may be configured to reflect light which is used for EUV lithography. Typically, the exposure wavelength in UV lithography may be 13.5 nm. For example, the reflective layer stack may therefore have a reflective effect for an exposure wavelength of 13.5 nm. In one example, the reflective layer stack ML may adjoin the substrate S, such that there is an interface between the reflective layer stack ML and the substrate S.

The mask M may comprise a backside layer B. The backside B may adjoin the substrate S. The backside B may, for example, be electrically conductive in order to enable suitable mounting of the EUV mask M.

The mask M may further comprise a cap layer C. The cap layer may serve for mechanical and/or chemical protection of the reflective layer stack ML. The cap layer C may comprise, for example, ruthenium and/or rhodium. Generally, the cap layer may comprise a thin layer. For example, a thickness of the cap layer C may be smaller than 10 nm, preferably smaller than 8 nm, more preferably smaller than 6 nm, even more preferably smaller than 4 nm, most preferably smaller than 2 nm. The cap layer may adjoin the substrate layer stack ML, such that there is an interface between the reflective layer stack ML and the cap layer, and such that the layer stack ML is protected by the cap layer.

In addition, the mask M may comprise one or more imaging structures P. An imaging structure P may be configured to absorb an exposure wavelength for EUV lithography. In addition, or alternatively, the imaging structure P may be configured to cause a phase shift in the exposure wavelength for EUV lithography. The EUV mask may thus also comprise a phase-shifting EUV mask. Generally, the one or more imaging structures P on the reflective layer stack ML may be designed such that a lithography image with a defined pattern can be created in the case of lithography in a target plane. In some embodiments, the imaging structure P may comprise three layers, e.g., the layers P1, P2 and P3. In addition, or alternatively, the imaging structure P may comprise less or more than three layers.

The imaging structure P may extend from the cap layer C. For example, the layer P3 may extend from the cap layer C. In addition, the layer P3 may define an osculation surface with the cap layer C. As illustrated in FIG. 11A, the mask M comprises two imaging structures and/or pattern elements P that may be adjacent to each other. In particular, the mask illustrated in FIG. 11A may comprise a low aspect ratio, e.g., the ratio of the distance between two neighboring imaging structures and the height of the imaging structures may be relatively low. Specifically, a relatively low aspect ratio may comprise that a distance between neighbouring imaging structures P of the mask is similar or even lower than a height of the imaging structures P.

Generally, the cap layer C may comprise a defect D. For example, the defect D of the cap layer C may comprise a deviation of a thickness of the cap layer. For example, the thickness of the cap layer C may deviate from a target thickness of the cap layer C. Generally, the target thickness of the cap layer C may be such as to ensure the protective function of the cap layer. The deviation of the thickness of the cap layer C in the region of the defect D may be such that the thickness is reduced, e.g., a cap layer material may be absent in the region associated with the defect D. In addition, or alternatively, the defect D may comprise a variance of the chemical composition of the cap layer C, e.g., a deviation from a target chemical composition of the cap layer C. For example, the chemical variation of the cap layer C in the region associated with the defect D may be such as to at least partially degrade the protective function of the cap layer C. The defect D of the cap layer C may generally at least partially be located between the imaging structures P of the mask, e.g., the imaging structures P of the mask may surround and/or encompass the defect D of the mask M. In particular, the defect D may separate the imaging structures P of the mask M. Although the defect D is illustrated as a clearly distinguishable defect, e.g., comprising a sharp boundary, generally the defect D may not be spatially clearly defined. For example, the boundary of the defect D may be continuous and/or may comprise multiple steps. Specifically, the defect D may be such that a resolution of the precise boundary of the defect by a SEM is rendered impossible.

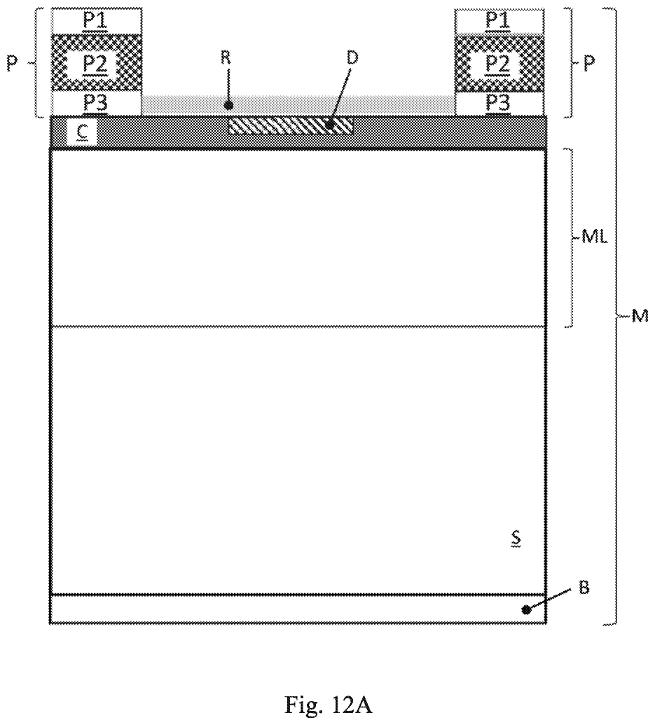

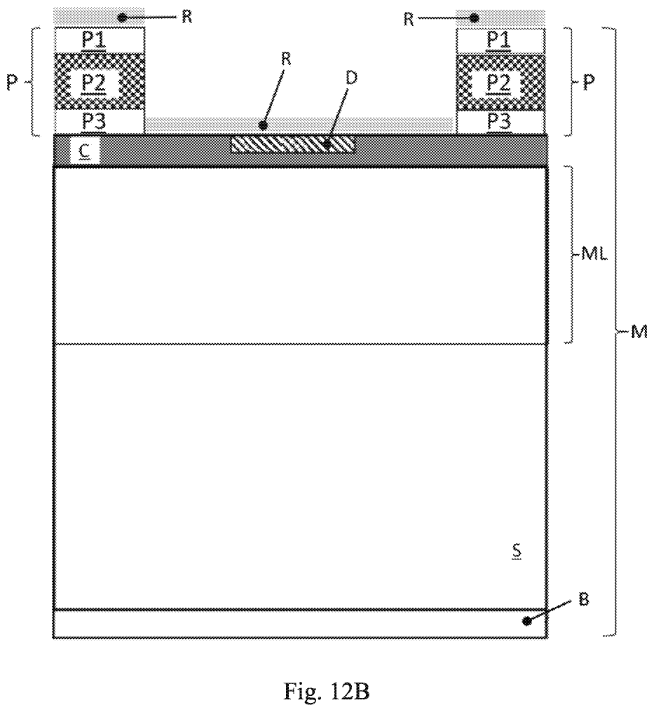

According to aspects, it might be advantageous to remove at least a portion of an imaging structure P of the mask M, particularly when the aspect ratio associated with the mask M is low. Removing at least a portion of an imaging structure P of the mask M may comprise removing at least a portion of the imaging structure P located within a vicinity of the defect D. As illustrated in FIGS. 11B and 11C, the neighbouring imaging structures P may be completely removed, e.g., all layers P1, P2 and P3 of the imaging structure P may be removed, in a vicinity of the defect D. In particular (see FIG. 11B), the imaging structure P may be removed such as to at least partially expose a portion of the capping layer C located beneath the imaging structure P. Generally, whether at least a portion of an imaging structure P of the mask M is removed or not may be at least partially based on a size of the defect D. For example, when the size of the defect D is larger than a threshold, at least a portion of an imaging structure P of the mask M may be removed (FIGS. 11B and 11C). In particular, when the size of the defect does not exceed the threshold, the at least a portion of an imaging structure P of the mask M may not be removed (see FIGS. 12A and 12B). The removal may be carried out by particle, e.g., electron, beam assisted etching using one or more precursor gases, e.g., one or more etching gases and one or more additive gases.

According to aspects, the repair of the defect D of the cap layer C may comprise depositing a deposition material R on at least a portion of the cap layer C and/or a multilayer ML of the mask M. For example, the deposition material R may be deposited such as to at least cover the defect D. Specifically, the deposition material R may be deposited such as to essentially cover the defect D only (see FIG. 11B). For example, depositing the deposition material such as to cover the defect D essentially only may be advantageous when the size of the defect D is smaller than a threshold.

Alternatively (see FIG. 11C), depositing the deposition material R may comprise depositing the deposition material R such that a lateral extension of the deposited deposition material R exceeds a lateral extension associated with the defect D of the cap layer C. For example, the deposited deposition material R may cover the defect D and at least a portion of the defect-free cap layer C. However, the deposited deposition material R may not extend arbitrarily. In particular, the lateral extension of the deposited deposition material R may be bounded by the (initial) imaging structure of the mask. For example, the lateral extension of the deposited deposition material R may be bounded based on the position of the (removed) imaging structure P.

Specifically, the deposited deposition material R may continuously extend between an outer end point of a position associated with a first neighboring imaging structure P (e.g., the left imaging structure P in FIG. 11A) and an outer end point of a position associated with a second neighbouring imaging structure P (e.g., the right imaging structure P in FIG. 11B). In particular, the deposited deposition material R may continuously extend between the (initial, e.g., before the removing) neighbouring imaging structures P such as to at least partially cover the osculation surface between the lowest layer P3 of the imaging structure P and the cap layer C. For example, the deposited deposition material R may continuously extend between the neighbouring imaging structures P such that the end points of the deposited deposition material R may comprise the outer edges of the respective osculation surface. In other examples, the deposition material R may be deposited such as to extend just until the inner edges of the respective pattern elements that were removed.

After the deposition of the deposition material R at least a portion of the removed imaging structure P of the mask may be reconstructed (see FIG. 11D). In particular, reconstructing the imaging structure P may comprise reconstructing the imaging structure P such as to reconstruct optical properties of the mask M. For example, reconstructing the imaging structure P such as to reconstruct optical properties of the mask M may comprise to reconstruct and/or to rebuild the (initial) imaging structure P by a reconstructed imaging structure P.

Specifically, the reconstructed imaging structure P may be reconstructed above the deposited deposition material R. For example, the reconstructed imaging structure P may not contact the original cap layer C but the deposited deposition material R. In particular, the reconstructed imaging structure P and the deposited deposition material R may define an osculation surface.

Generally, the reconstructed imaging structure P may be located and/or positioned essentially in the same region as the (initial) imaging structure P. In some embodiments, the reconstructed imaging structure P may comprise one layer, e.g., the reconstructed imaging structure P may comprise a coherent block. In addition, or alternatively, the reconstructed imaging structure P may comprise two layers, or more.

FIGS. 12A and 12B illustrate a further exemplary embodiment of a repair of a defect D of a cap layer C of a mask M. For example, the repair of the defect D of the cap layer C may comprise to maintain the (initial) imaging structure P. For example, the repair of the defect D of the cap layer C may comprise depositing the deposition material in a clear region between the imaging structure P, e.g., without removing the imaging structure P. For example, repairing the defect D of the cap layer C without removing the imaging structure P of the mask M may be advantageous when the aspect ratio of the imaging structures is relatively high and/or when the defect D is relatively small, e.g., small compared to a size of a clear region C associated with the defect and/or smaller than a defect size threshold.

For example (see FIG. 12A), the deposition material R may be deposited such as to extend between the imaging structures P of the mask M. For example, extending between the imaging structures P of the mask M may comprise that no deposition material R is deposited on an upper and/or top surface of an imaging structure P. In particular, extending between the imaging structures P of the mask M may comprise that no deposition material R is deposited on the top surface of the uppermost layer P1 of the imaging structure P. Specifically, depositing the deposition material R such that no deposition material R is deposited on the top surface of the imaging structure P may comprise that a particle beam associated with the deposition of the deposition material is not directed within a vicinity of the imaging structure P. For example, the particle beam for depositing the deposition material R may be directed such as to maintain a (predefined) distance to the imaging structure P. Specifically, directing the particle beam such as to maintain a (predefined) distance to the imaging structure may allow for depositing deposition material R also in the vicinity (to which the particle beam is not directed) of the imaging structure P via secondary electrons, thereby ensuring that the deposited deposition material R extends towards the imaging structure P (see, e.g., FIG. 12A). In addition, directing the particle beam such as to maintain a (predefined) distance to the imaging structure P may ensure that no deposition material is deposited on top of the imaging structure P. In particular, as the imaging structure P defines additional material as well as edges, a secondary electron yield (SEY) may be large within the vicinity of the imaging structure, thereby causing deposition of deposition material. Thus, by directing the particle beam such as to maintain a (predefined) distance to the imaging structure P, deposition effects caused by the enlarged SEY within the vicinity of the imaging structure P may be mitigated.

In addition, or alternatively (see FIG. 12B), the deposition material R may be deposited such as to extend between the imaging structures P of the mask M and deposition material R may also be deposited on an upper and/or top surface of an imaging structure P. For example, deposition material R may be deposited on an upper and/or top surface of an uppermost layer P1 of the imaging structure P. For example, depositing deposition material R on an upper and/or top surface of an uppermost layer P1 of the imaging structure P may comprise directing a particle beam associated with the deposition at the imaging structure P. Generally, the deposition material R may be deposited such on an upper and/or top surface of an uppermost layer P1 of the imaging structure P as to form a homogeneous layer, e.g., with a constant thickness. Specifically, depositing deposition material R on an upper and/or top surface of an imaging structure P, particularly homogenously, ensures that the deposition material R forms a homogenous layer along the region extending between a first outer end of a pattern element P (e.g., the left pattern element P) and a second outer end of a pattern element P (e.g., the right pattern element P).

Forming a homogenous layer along the region extending between a first outer end of a pattern element P may minimize the local variances in the optical properties of the mask, e.g., local fluctuations in an intensity and/or a phase shift, and thereby optimize the optical properties of the mask.

### Further Embodiments

Embodiment 1: Method of processing a mask (M) for lithography, comprising:
providing a gas and a particle beam on the mask in order to at least partly eliminate any chemical and/or geometric variance of a defect site (D) in a layer sequence (C, ML) of the mask from a target property, wherein the layer sequence (C, ML) is adjoined by an imaging structure (P) of the mask and the layer sequence comprises one or more layers.

Embodiment 2: Method according to Embodiment 1, wherein there is a variance in a thickness of a material of the layer sequence at the defect site.

Embodiment 3: Method according to Embodiment 1 or 2, wherein a material in the layer sequence is absent at the defect site.

Embodiment 4: Method according to any of Embodiments 1-3, wherein there is a variance in the chemical composition at the defect site.

Embodiment 5: Method according to any of Embodiments 1-4, wherein there is a variance in the surface roughness at the defect site.

Embodiment 6: Method according to any of Embodiments 1-5, wherein the providing of the gas comprises providing a deposition gas for deposition of deposition material at the defect site.

Embodiment 7: Method according to Embodiment 6, wherein the deposition gas comprises ruthenium.

Embodiment 8: Method according to either of Embodiments 6 and 7, wherein the deposition gas comprises at least one of the following:
allylruthenium(II) tricarbonyl bromide, allylruthenium(II) tricarbonyl chloride, benzeneruthenium(II) chloride dimer, bis(2,4-dimethylpentadienyl)ruthenium, bis(cyclopentadienyl)ruthenium(II), bis(ethylcyclopentadienyl)ruthenium(II), carbonylchlorohydridotris(triphenylphosphine)ruthenium(II), chloro(4,4′-dicarboxy-2,2′-bipyridine)(p-cymene)ruthenium(II) chloride, chloro(cyclopentadienyl)bis(triphenylphosphine)ruthenium(II), chloropentaammineruthenium(III) chloride, dicarbonylcyclopentadienylruthenium dimer, dichloro(p-cymene)ruthenium(II) dimer, dichlorotricarbonylruthenium(II) dimer, dichlorotris(triphenylphosphine)ruthenium(II), dihydrotetrakis(triphenylphosphine)ruthenium(II), hexaammineruthenium(III) chloride, (hexamethylbenzene)ruthenium(II) dichloride dimer, (p-cymene)(N,N′-diisopropyl-1,2-ethanediimine)ruthenium, ruthenium pentacarbonyl, ruthenium tetracarbonyl iodide, ruthenium(III) acetylacetonate, ruthenium(III) bromide, ruthenium(III) chloride, ruthenium(III) nitrosylacetate, ruthenium(III) nitrosylchloride monohydrate, ruthenium(III) nitrosylnitrate, ruthenium(III) nitrosylsulfate, ruthenium(IV) sulfide, ruthenium(VIII) oxide, tetraamminechlorohydroxyruthenium(III) chloride, tetrakis(dimethyl sulfoxide)dichlororuthenium(II), (toluene)(1,5-cyclooctadiene)ruthenium, triruthenium dodecacarbonyl, tris(2,2′-bipyridyl)ruthenium(II) chloride.

Embodiment 9: Method according to any of Embodiments 6-8, wherein the deposition gas comprises rhodium.

Embodiment 10: Method according to any of Embodiments 6-9, wherein the deposition gas comprises at least one of the following:
acetylacetonatobis(ethylene)rhodium(I), chlorobis(ethylene)rhodium(I) dimer, dicarbonyl(2,4-pentanedionato)rhodium(I), di-eta-chloro-tetrakis(phosphorus trifluoride)dirhodium, dirhodium(II) tetrakis(caprolactam), di-μ-chloro-tetracarbonyldirhodium(I), hexarhodium hexadecacarbonyl, hydridotetrakis(triphenylphosphine)rhodium(I), pentaamminechlororhodium(III) dichloride, rhodium octanoate dimer, rhodium(II) acetate dimer, rhodium(II) trifluoroacetate dimer, rhodium(III) acetate, rhodium(III) chloride trihydrate, rhodium(III) chloride, rhodium(III) nitrate (anhydrous), rhodium(III) oxide (anhydrous), rhodium(III) trifluoroacetylacetonate, tetrakis(1,5-cyclooctadiene)tetra-μ-hydridotetrarhodium, tetrarhodium dodecacarbonyl.

Embodiment 11: Method according to any of Embodiments 6-10, wherein the deposition gas comprises boron.

Embodiment 12: Method according to any of Embodiments 6-11, wherein the deposition gas comprises silicon.

Embodiment 13: Method according to any of Embodiments 6-12, wherein the deposition gas comprises titanium.

Embodiment 14: Method according to any of Embodiments 6-13, wherein the deposition gas comprises zirconium.

Embodiment 15: Method according to any of Embodiments 6-14, wherein the deposition gas comprises palladium.

Embodiment 16: Method according to any of Embodiments 6-15, wherein the deposition gas comprises niobium.

Embodiment 17: Method according to any of Embodiments 1-16, wherein the providing of the gas comprises providing an etch gas for removal of material at the defect site.

Embodiment 18: Method according to Embodiment 17, wherein the providing of the etch gas causes etching of material in the layer sequence.

Embodiment 19: Method according to either of Embodiments 17 and 18, wherein the providing of the etch gas causes etching of extraneous material at the defect site which is essentially absent at a non-defect site of the layer sequence.

Embodiment 20: Method according to any of Embodiments 17-19, wherein the etch gas comprises a halogen.

Embodiment 21: Method according to any of Embodiments 17-20, wherein the halogen comprises fluorine.

Embodiment 22: Method according to any of Embodiments 17-21, wherein the etch gas comprises xenon difluoride.

Embodiment 23: Method according to any of Embodiments 17-22, wherein the provision of the etch gas for removal of material at the defect site is followed by deposition of deposition material at the defect site.

Embodiment 24: Method according to any of Embodiments 17-23, wherein the providing of the etch gas causes removal of at least one substance intercalated in the layer sequence.

Embodiment 25: Method according to any of Embodiments 1-24, wherein the layer sequence comprises one or more outer layers (C) for protection of a reflective layer stack (ML) of the mask, and the one or more outer layers comprise the defect site (D).

Embodiment 26: Method according to Embodiment 25, wherein at least one of the one or more outer layers comprises ruthenium.

Embodiment 27: Method according to either of Embodiments 25 and 26, wherein at least one of the one or more outer layers comprises rhodium.

Embodiment 28: Method according to any of Embodiments 1-27, wherein the layer sequence comprises one or more layers of a reflective layer stack (ML) of the mask, and the one or more layers of the reflective layer stack comprise the defect site (D).

Embodiment 29: Method according to Embodiment 28, further comprising:
providing an etch gas and a particle beam for removal of material in order to expose part of the reflective layer stack, such that the chemical and/or geometric variance of the defect site from the target property can be at least partly eliminated.

Embodiment 30: Method according to any of Embodiments 1-29, wherein the mask comprises a mask for EUV lithography.

Embodiment 31: Computer program comprising instructions for executing a method according to any of Embodiments 1-30.

Embodiment 32: Device for processing a mask (M) for lithography, comprising:
means of providing a gas and a particle beam on the mask in order to at least partly eliminate any chemical and/or geometric variance of a defect site (D) in a layer sequence (C, ML) of the mask from a target property, wherein the layer sequence is adjoined by an imaging structure (P) of the mask and the layer sequence comprises one or more layers; a computer system comprising the computer program according to Embodiment 31.

What is claimed is:

1. A method for repairing a defect of a cap layer of a mask for lithography, comprising depositing a deposition material on at least a portion of the cap layer and/or a multilayer of the mask, such that at least the defect of the cap layer is covered by the deposition material, wherein a lateral extension of the deposited deposition material exceeds a lateral extension associated with the defect of the cap layer.

2. The method for repairing according to claim 1, wherein the defect of the cap layer comprises a variance in a thickness of the cap layer.

3. The method for repairing according to claim 2, wherein the variance in the thickness comprises an absence of a cap layer material.

4. The method for repairing according to claim 1, wherein the defect of the cap layer comprises a variance in a chemical composition of the cap layer material.

5. The method for repairing according to claim 4, wherein the variance in the chemical composition is associated with a degradation of a protective function of the cap layer.

6. The method for repairing according to claim 1, wherein the defect of the cap layer is repaired such as to at least partially restore a protective function of the cap layer.

7. The method for repairing according to claim 6, wherein the defect of the cap layer is repaired such as to at least partially restore the protective function with respect to the multilayer stack of the mask.

8. The method for repairing according to claim 1, wherein the defect of the cap layer of the mask is repaired without modifying the multilayer of the mask.

9. The method for repairing according to claim 1, wherein at least one of: the lateral extension of the deposited deposition material exceeds the lateral extension associated with the defect in two directions; or the lateral extension of the deposited deposition material is bounded in at least one direction by an imaging structure of the mask.

10. The method for repairing according to claim 9, wherein the imaging structure bounding the lateral extension of the deposited deposition material comprises neighbouring pattern elements of the mask.

11. The method for repairing according to claim 1, further comprising:
removing at least one portion of an imaging structure of the mask, wherein the at least one portion of the imaging structure is located within a vicinity of the defect.

12. The method for repairing according to claim 11, wherein the at least one portion of the imaging structure of the mask comprises at least one pattern element of the mask.

13. The method for repairing according to claim 11, wherein at least one of: the at least one portion of the imaging structure is removed such as to at least partially expose a portion of the capping layer located beneath the imaging structure; or depositing the deposition material comprises:
depositing the deposition material in a region of the mask associated with the removed imaging structure of the mask.

14. The method for repairing according to claim 11, further comprising:
reconstructing at least one portion of the removed imaging structure of the mask.

15. The method for repairing according to claim 1, wherein the at least one portion of the imaging structure is reconstructed such as to reconstruct the optical properties of the mask.

16. The method for repairing according to claim 14, wherein reconstructing at least the portion of an imaging structure comprises reconstructing the portion of the imaging structure above the deposited deposition material.

17. The method for repairing according to claim 1, further comprising at least one of:
detecting and/or analyzing the defect of the cap layer, or detecting and/or analyzing the defect of the cap layer is at least partially based on an aerial image and/or an atomic force microscopy image of at least a portion of the mask.

18. The method for repairing according to claim 1, wherein depositing the deposition material comprises providing a deposition gas and a particle beam on the mask.

19. The method for repairing according to claim 18, wherein the deposition gas comprises at least one of ruthenium or rhodium.

20. The method for repairing according to claim 18, wherein the deposition gas comprises at least one of the following:
allylruthenium(II) tricarbonyl bromide, allylruthenium(II) tricarbonyl chloride, benzeneruthenium(II) chloride dimer, bis(2,4-dimethylpentadienyl)ruthenium, bis(cyclopentadienyl)ruthenium(II), bis(ethylcyclopentadienyl)ruthenium(II), carbonylchlorohydridotris(triphenylphosphine)ruthenium(II), chloro(4,4′-dicarboxy-2,2′-bipyridine)(p-cymene)ruthenium(II) chloride, chloro(cyclopentadienyl)bis(triphenylphosphine)ruthenium(II), chloropentaammineruthenium(III) chloride, dicarbonylcyclopentadienylruthenium dimer, dichloro(p-cymene)ruthenium(II) dimer, dichlorotricarbonylruthenium(II) dimer, dichlorotris(triphenylphosphine)ruthenium(II), dihydrotetrakis(triphenylphosphine)ruthenium(II), hexaammineruthenium(III) chloride, (hexamethylbenzene)ruthenium(II) dichloride dimer, (p-cymene)(N,N′-diisopropyl-1,2-ethanediimine)ruthenium, ruthenium pentacarbonyl, ruthenium tetracarbonyl iodide, ruthenium(III) acetylacetonate, ruthenium(III) bromide, ruthenium(III) chloride, ruthenium(III) nitrosylacetate, ruthenium(III) nitrosylchloride monohydrate, ruthenium(III) nitrosylnitrate, ruthenium(III) nitrosylsulfate, ruthenium(IV) sulfide, ruthenium(VIII) oxide, tetraamminechlorohydroxyruthenium(III) chloride, tetrakis(dimethyl sulfoxide)dichlororuthenium(II), (toluene)(1,5-cyclooctadiene)ruthenium, triruthenium dodecacarbonyl, tris(2,2′-bipyridyl)ruthenium(II) chloride;
acetylacetonatobis(ethylene)rhodium(I), chlorobis(ethylene)rhodium(I) dimer, dicarbonyl(2,4-pentanedionato)rhodium(I), di-eta-chloro-tetrakis(phosphorus trifluoride)dirhodium, dirhodium(II) tetrakis(caprolactam), di-μ-chloro-tetracarbonyldirhodium(I), hexarhodium hexadecacarbonyl, hydridotetrakis(triphenylphosphine)rhodium(I), pentaamminechlororhodium(III) dichloride, rhodium octanoate dimer, rhodium(II) acetate dimer, rhodium(II) trifluoroacetate dimer, rhodium(III) acetate, rhodium(III) chloride trihydrate, rhodium(III) chloride, rhodium(III) nitrate (anhydrous), rhodium(III) oxide (anhydrous), rhodium(III) trifluoroacetylacetonate, tetrakis(1,5-cyclooctadiene)tetra-μ-hydridotetrarhodium, tetrarhodium dodecacarbonyl.

21. The method for repairing according to claim 18, wherein the deposition gas comprises at least one of: boron, silicon, titanium, zirconium, palladium, niobium, or molybdenum.

22. A device for repairing a defect of a cap layer of a mask for lithography, comprising:
means for obtaining a characterization of the defect of the cap layer of the mask; and
means for automatically depositing a deposition material on at least a portion of the cap layer and/or a multilayer of the mask, such that at least the defect of the cap layer is covered by the deposition material.

23. The device for repairing according to claim 22, wherein the means for obtaining comprises an interface adapted to receive an aerial image of at least a portion of the mask comprising the defect.

24. The device for repairing according to claim 22, wherein the means for obtaining comprises an interface adapted to receive an atomic force microscopy image of at least a portion of the mask comprising the defect.

25. The device for repairing according to claim 22, further comprising means for determining a repair shape and/or a repair workflow for the mask, at least partially based on the characterization of the defect of the cap layer.
